(19) United States
(12) Patent Application Publication
(10) Pub. No.: US 2016/0118284 A1
(43) Pub. Date: Apr. 28, 2016

(54) PLASMA PROCESSING APPARATUS

(71) Applicant: PANASONIC INTELLECTUAL PROPERTY MANAGEMENT CO., LTD., Osaka (JP)

(72) Inventors: Tetsuhiro IWAI, Osaka (JP); Shogo OKITA, Hyogo (JP); Syouzou WATANABE, Hyogo (JP)

(21) Appl. No.: 14/919,325

(22) Filed: Oct. 21, 2015

(30) Foreign Application Priority Data
Oct. 22, 2014 (JP) 2014-215147
Feb. 4, 2015 (JP) 2015-020415

(51) Int. Cl. H01L 21/683

(52) U.S. Cl. CPC H01L 21/6831

(57) ABSTRACT

A plasma processing apparatus includes: a vessel which includes a reaction chamber, atmosphere within the reaction chamber capable of being depressurized; a lower electrode which supports an object to be processed within the reaction chamber; a dielectric member which comprises a first surface and a second surface opposite to the first surface, and which closes an opening of the vessel such that the first surface opposes an outside of the reaction chamber and the second surface opposes the object to be processed; and a coil which opposes the first surface of the dielectric member, and which generates plasma within the reaction chamber. An electrode pattern and an insulation film which covers the electrode pattern are formed on the second surface of the dielectric member.

### CROSS-REFERENCE TO RELATED APPLICATION(S)

This application is based on and claims priority from Japanese Patent Application No. 2014-215147 filed on Oct. 22, 2014 and Japanese Patent Application No. 2015-020415 filed on Feb. 4, 2015, the entire contents of which are incorporated herein by reference.

### BACKGROUND

1. Field of the Invention

One or more embodiments of the present invention relate to a plasma processing apparatus of an inductively coupled plasma (ICP) type, for example, a plasma processing apparatus used for manufacturing semiconductor elements or electric components.

2. Description of Related Art

A plasma processing apparatus an inductively coupled plasma (ICP) type generates a dielectric magnetic field by supplying radio frequency power from a radio frequency power supply to an induction coil disposed outside a reaction chamber. The dielectric magnetic field passes through a dielectric member which closes an opening of the reaction chamber, and acts on an inner space of the reaction chamber in which material gas is introduced, whereby inductively coupled plasma is generated in the reaction chamber. Due to physical and chemical reaction between radicals or ions in the plasma and an object to be processed, the object to be processed is etched.

In a case in which the object to be processed contains non-volatile material, non-volatile material produced by the reaction between the ions or radicals in the plasma and the object to be processed may adhere to the dielectric member closing the reaction chamber or a cover provided for protecting the dielectric member from the plasma. The cover is also formed by dielectric material. The non-volatile material adhering to the dielectric member and/or the cover (i.e., adhering substance) is likely to be exfoliated during a process of the plasma processing, and may float within the reaction chamber. As a result, the object to be processed may be contaminated.

In the mean time, in order to stabilize the process of the plasma processing, the dielectric member is heated to a predetermined temperature range. The dielectric member is heated, for example, by a heater located between the dielectric member and a coil (see JP-A-2008-226857). The heating of the dielectric member also contributes to suppression of adhesion of the non-volatile material to the dielectric member and/or the cover.

In a case in which the object to be processed contains conductive non-volatile material such as noble metal, the substance adhering to the dielectric member and/or the cover also has conductive properties. The conductive adhering substance inhibits the dielectric magnetic field radiated by the induction coil from passing into the reaction chamber, which reduces generation of the plasma within the reaction chamber.

In order to address the conductive adhering substance, a Faraday shield electrode (hereinafter referred to as an FS electrode) is provided on the dielectric member on the reaction chamber side, and the substance adhering to the dielectric member and/or the cover is actively removed (see JP-A-2008-130651, JP-A-2013-033860 and JP-A-2008-159660).

Further, in order to uniformly distribute the material gas, JP-A-2005-209885 teaches a method in which the inside of the reaction chamber is showered with the material gas through the cover having a plurality of gas injection ports.

### SUMMARY

Since the heater is located between the dielectric member and the coil as described above, the dielectric member is heated from an atmosphere side. When adhesion of the non-volatile material is to be suppressed by heating the dielectric member, it is preferable to sufficiently heat a surface of the dielectric member on the reaction chamber side. Consequently, in order to efficiently suppress the adhesion of the non-volatile material, it is necessary to supply high electric power to the heater for increasing temperature of the surface of the dielectric member on the reaction chamber side.

Similarly, in JP-A-2008-226857 and JP-A-2008-130651, the FS electrode is provided between the dielectric member and the coil, i.e., on the outside of the reaction chamber (atmosphere side). In the method, the radio frequency power is supplied from the radio frequency power supply to the FS electrode provided on the atmosphere side to generate bias voltage at an inside of the reaction chamber (vacuum side). Therefore, in order to obtain the bias effect which is sufficient for removing the non-volatile film, this method also requires supply of high electric power.

As described in JP-A-2008-159660, the FS electrode is provided, and the radio frequency power is supplied to the FS electrode, whereby the substance adhering to the cover is removed. Consequently, even when the plasma processing is repeatedly performed, the dielectric magnetic field generated by the induction coil can stably pass into the reaction chamber. Further, by using the cover having the plurality of gas injection ports as described in JP-A-2005-209885, variation of distribution of the material gas supplied into the reaction chamber is reduced, and etching uniformity in a surface of the object to be processed can be improved.

However, if the removal of adhering substance using the FS electrode is subject to the cover having the gas injection ports, the gas injection port formed in the cover may be etched. Consequently, the diameter of the gas injection port is changed from original size. As a result, a supply pattern of the material gas supplied through the gas injection ports is changed, and stable etching is hardly performed. Although the cover may be exchanged in this case, if the exchange frequency of the cover is increased, productivity is decreased.

An object of one or more embodiments of the present invention is to provide a plasma processing apparatus which can efficiently suppress adhesion of non-volatile material to the dielectric member and which is simple in structure and excellent in maintainability.

Another object of one or more embodiments of the present invention is to perform stable plasma processing and to increase productivity.

An aspect of the present invention provides a plasma processing apparatus including: a vessel which includes a reaction chamber, atmosphere within the reaction chamber capable of being depressurized; a lower electrode which supports an object to be processed within the reaction chamber; a dielectric member which includes a first surface and a second surface opposite to the first surface, and which closes an opening of the vessel such that the first surface opposes an outside of the reaction chamber and the second surface opposes the object to be processed; and a coil which opposes the first surface of the dielectric member, and which generates plasma within the reaction chamber, wherein an electrode pattern and an insulation film which covers the electrode pattern are formed on the second surface of the dielectric member.

Another aspect of the present invention provides a plasma processing apparatus including: a reaction chamber; a stage which supports an object to be processed within the reaction chamber; a cover which opposes the stage within the reaction chamber; a Faraday shield electrode which is disposed on an opposite side of the stage across the cover; a dielectric member which is disposed on the opposite side of the stage across the cover, and which closes an opening of the reaction chamber; and an induction coil which is disposed on an outer side of the dielectric member opposite to the reaction chamber, wherein the Faraday shield electrode has at least one of a slit portion and a window portion, wherein a gas introduction path into which material gas of plasma is introduced is formed between the cover and the dielectric member, and wherein the cover has a gas injection port which is formed in a portion opposing at least a part of the slit portion and the window portion, and through which the material gas introduced into the gas introduction path is supplied into the reaction chamber.

According to the plasma processing apparatus of an aspect of the present invention, since the electrode pattern of the electric heater and/or the plate electrode is disposed on the reaction chamber side of the dielectric member, it is possible to efficiently suppress adhesion of the non-volatile material.

According to the plasma processing apparatus of another aspect of the present invention, since the change of diameter of the gas injection port is suppressed, the supply pattern of the material gas is hardly changed. Consequently, even when the plasma processing is repeatedly performed, it is possible to stably etch the object to be processed. Further, damage to the cover is suppressed, the exchange frequency of the cover can be reduced, and excellent productivity can be obtained.

### BRIEF DESCRIPTION OF THE DRAWINGS

FIG. 1 is a cross-sectional view schematically showing a structure of a plasma processing apparatus according to a first embodiment of the present invention;

FIG. 2A is a vertical cross-sectional view schematically showing a structure of a dielectric member and an electrode pattern according to the first embodiment, and FIG. 2B is a vertical cross-sectional view obtained by enlarging a size of the structure of FIG. 2A in a vertical direction;

FIG. 3 is a plan view of a first electrode pattern (an electric heater) according to the first embodiment;

FIG. 4 is a plan view of a second electrode pattern (a plate electrode) according to the first embodiment;

FIG. 5A is a vertical cross-sectional view schematically showing an arrangement of the dielectric member and a coil according to the first embodiment, and FIG. 5B is a plan view of the dielectric member;

FIG. 6 is a vertical cross-sectional view schematically showing a structure of a dielectric member and an electrode pattern according to a second embodiment of the present invention;

FIG. 7A is a vertical cross-sectional view schematically showing an arrangement of a dielectric member and a coil according to a third embodiment of the present invention, and FIG. 7B is a plan view of the dielectric member;

FIG. 8A is a vertical cross-sectional view schematically showing an arrangement of a dielectric member and a coil according to a fourth embodiment of the present invention, and FIG. 8B is a plan view of the dielectric member;

FIG. 9 is a cross-sectional view schematically showing a structure of a plasma processing apparatus according to a fifth embodiment of the present invention;

FIG. 10A is a plan view of an FS electrode layer according to the fifth embodiment, FIG. 10B is a plan view of a cover, and FIG. 10C is a plan view of the FS electrode layer and the cover provided in the plasma processing apparatus as viewed from the FS electrode layer side;

FIG. 11 is a plan view of a coil according to the fifth embodiment;

FIG. 12A is a plan view of an FS electrode layer according to a sixth embodiment, FIG. 12B is a plan view of a cover, and FIG. 12C is a plan view of the FS electrode layer and the cover provided in the plasma processing apparatus as viewed from the FS electrode layer side;

FIG. 13A is a top view schematically showing a structure of a cover and a second holder provided in a plasma processing apparatus according to a seventh embodiment;

FIGS. 13Ba to 13Bd are enlarged cross-sectional views cut along lines X1-X1, X2-X2, X3-X3 and X4-X4 shown in FIG. 13A, respectively;

FIG. 14 is a cross-sectional view schematically showing a structure of a plasma processing apparatus according to the seventh embodiment;

FIG. 15A is a top view schematically showing a structure of a cover and a second holder provided in a plasma processing apparatus according to an eighth embodiment;

FIGS. 15Ba to 15Be are enlarged cross-sectional views cut along lines Y1-Y1, Y2-Y2, Y3-Y3, Y4-Y4 and Y5-Y5 shown in FIG. 15A, respectively;

FIG. 16 is a cross-sectional view schematically showing a structure of a plasma processing apparatus according to a ninth embodiment;

FIG. 17 is a cross-sectional view schematically showing a structure of a plasma processing apparatus according to a tenth embodiment;

FIG. 18 is a plan view of an FS electrode layer and a heater electrode provided in the plasma processing apparatus according to the tenth embodiment as viewed from the heater electrode side;

FIG. 19 is a cross-sectional view schematically showing a structure of a plasma processing apparatus according to an eleventh embodiment; and

FIG. 20 is a cross sectional view schematically showing the cover and the FS electrode layer provided in the plasma processing apparatus according to the embodiments of the present invention.

### DETAILED DESCRIPTION

### First Embodiment

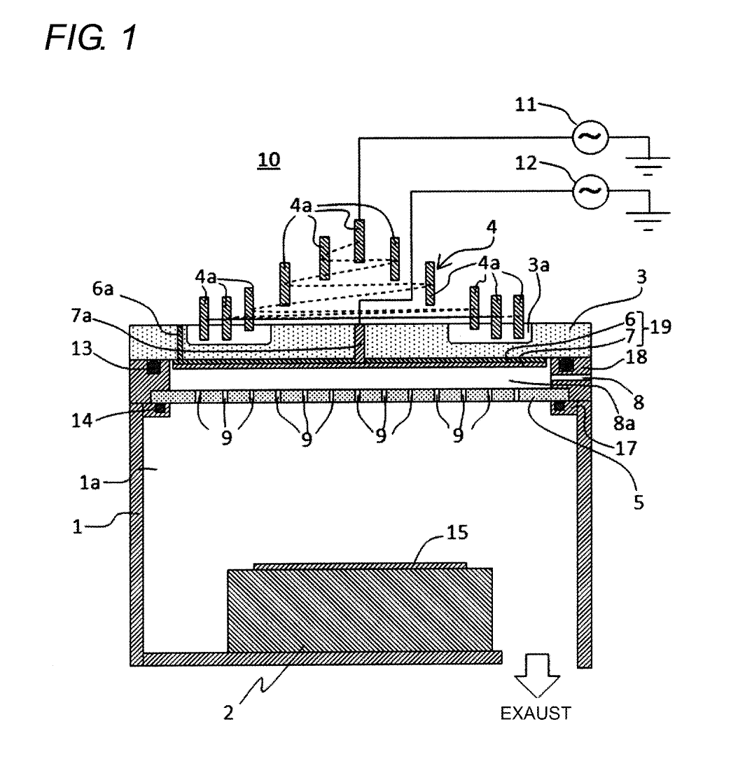

FIG. 1 shows a structure of a dry etching apparatus 10 of an inductively coupled plasma (ICP) type, which is a plasma processing apparatus according to a first embodiment of the present invention. The dry etching apparatus 10 includes a vessel 1 having a reaction chamber 1a in which an inner atmosphere can be depressurized, a lower electrode 2 which supports a substrate 15 as an object to be processed within the reaction chamber 1a, a dielectric member 3 which closes an opening of the vessel 1 and opposes the substrate 15, and a coil 4 which is disposed on an outer side of the dielectric member 3 opposite to the reaction chamber 1a and generates plasma within the reaction chamber 1a.

The vessel 1 has a substantially cylindrical shape with an opened top portion. The opening of the top portion is hermetically sealed by the dielectric member 3 as a lid. Atmosphere within the reaction chamber 1a is exhausted by a predetermined pumping device (not shown) and maintained at a depressurized atmosphere. The vessel 1 is provided with a gate (not shown) for loading the substrate 15 into the vessel and unloading it therefrom. Bias voltage is applied to the lower electrode 2. The lower electrode 2 may have a function of electrostatically chucking and holding the substrate 15 and may be provided with a circulation passage of refrigerant.

A first holder 17 for supporting a cover 5 is supported by an upper end of a side wall of the vessel 1, and the cover 5 is supported on the first holder 17 via a second elastic ring 14. An outer periphery of the cover 5 is fixed by a second holder 18 for supporting the dielectric member 3. The dielectric member 3 is supported on the second holder 18 via a first elastic ring 13. The cover 5 protects a surface of the dielectric member 3 on the reaction chamber 1a side from the plasma.

The second holder 18 is provided with a gas introduction port 8 for introducing material gas (process gas) of the plasma into the reaction chamber 1a from a predetermined gas supply source. The process gas stays within a fine gap 8a formed between the dielectric member 3 and the cover 5, and then is ejected into the reaction chamber 1a from a plurality of gas injection ports 9 formed in the cover 5. The plurality of gas injection ports 9 are preferably arranged, for example, in a concentric manner.

The vessel 1, the first holder 17, the second holder 18, etc., may be formed of metallic material having sufficient rigidity such as aluminum or stainless steel (SUS), or aluminum having a surface subjected to an anodizing treatment. The dielectric member 3, the cover 5, etc., may be formed of dielectric material such as yttrium oxide (Y₂O₃), aluminum nitride (AlN), alumina (Al₂O₃), or quartz (SiO₂) may be used.

The dielectric member 3 has a substantially circular plate shape in conformance with the opening shape of the vessel 1. A given electrode pattern and an insulation film covering the electrode pattern are formed on the dielectric member 3 on the reaction chamber 1a side. As used herein, a layer containing the electrode pattern and the insulation film covering the electrode pattern is referred to as an electrode layer 19.

The electrode pattern is formed by conductive material. Since the electrode pattern is formed on the dielectric member 3 on the reaction chamber 1a side, not on the atmosphere side (coil side), a groove for disposing at least a part of the coil 4 in the dielectric member 3 can be formed, as described later. Consequently, the distance between the coil 4 and the reaction chamber 1a can be reduced, and density of the plasma can be made higher.

The insulation film may be formed of dielectric material such as ceramics (for example, white alumina). The insulation film covers the electrode pattern, thereby capable of suppressing generation of metal contamination or particles caused by metal forming the electrode pattern within the reaction chamber 1a. The insulation film also suppresses damage to the electrode pattern caused by the process gas or the plasma.

The electrode pattern preferably includes, for example, an electric heater 6b which heats the dielectric member, or a plate electrode 7b which is capacitively coupled with the plasma within the reaction chamber 1a by supplying radio frequency power to the dielectric member 3. When the material generated from the object to be processed due to the plasma processing is non-volatile material, only the electrode layer containing the electric heater 6b may be provided. The electrode layer may be a laminate including a plurality of layers of the electrode patterns and insulation films. In this case, the electrode pattern preferably includes the electric heater 6b and the plate electrode 7b.

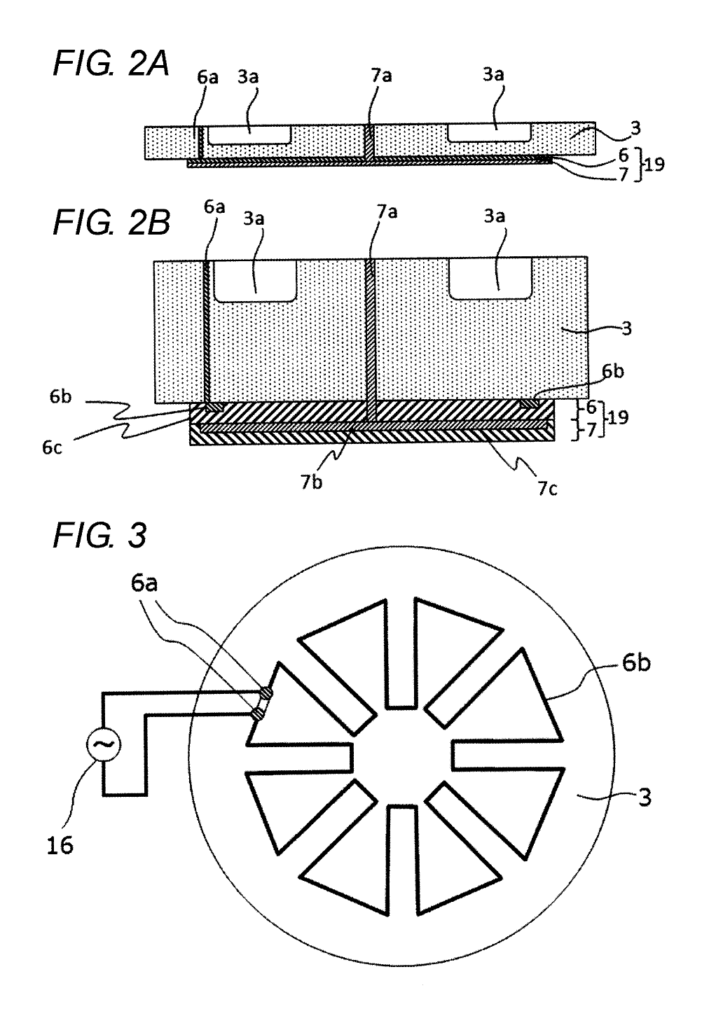

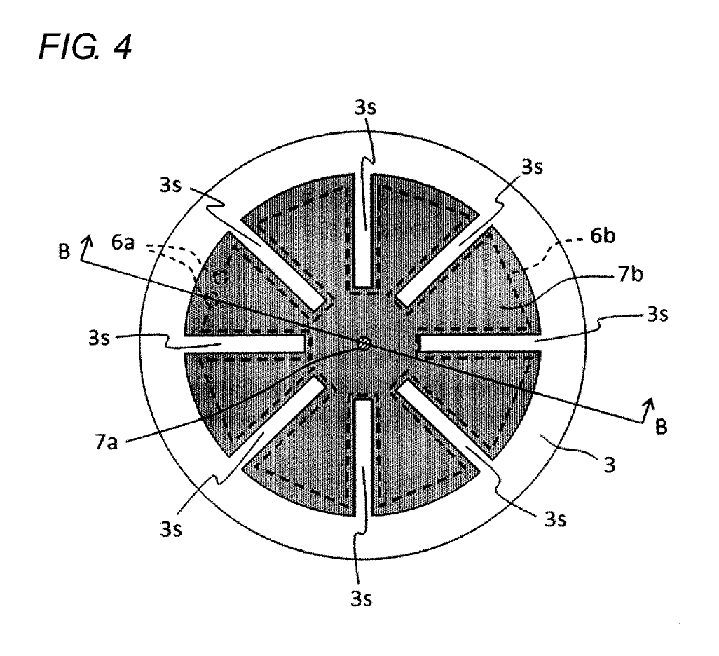

FIG. 2A is a vertical cross-sectional view schematically showing a structure of the dielectric member 3 and the electrode layer 19 according to the present embodiment. In FIG. 2B, a size of the dielectric member 3 and the electrode layer 19 is enlarged in a vertical direction (thickness direction) so as to facilitate understanding. FIGS. 2A and 2B are cross-sectional views cut along a line B-B shown in FIG. 4.

The electrode layer 19 shown in FIGS. 2A and 2B has a laminate structure including a first electrode layer 6 formed on a surface of the dielectric member 3 on the reaction chamber 1a side, and a second electrode layer 7 formed on a surface of the first electrode layer 6 on the reaction chamber 1a side. The first electrode layer 6 includes a first electrode pattern 6b formed on the surface of the dielectric member 3 and a first insulation film 6c which covers the first electrode pattern 6b. Similarly, the second electrode layer 7 includes a second electrode pattern 7b and a second insulation film 7c which covers the second electrode pattern 7b.

Hereinafter, an example in which the first electrode pattern 6b is the electric heater, and the second electrode pattern 7b is the plate electrode will be described.

Since the electric heater 6b is disposed on the surface of the dielectric member 3 on the reaction chamber 1a side, the surface of the dielectric member 3 on the reaction chamber 1a side can be heated efficiently by small electric power. Consequently, it is possible to efficiently suppress adhesion of the non-volatile material to the dielectric member 3 and the cover 5 by small electric power.

By forming Faraday shield (FS) in the vicinity of the dielectric member 3 as described above, adhesion of the non-volatile material to the dielectric member 3 and the cover 5 can be suppressed. Bias voltage is generated between the plasma and each of the dielectric member 3 and the cover 5 by supplying radio frequency power to the plate electrode 7b, and the plate electrode 7b functions as an FS electrode. The plate electrode 7b is also disposed on the surface of the dielectric member 3 on the reaction chamber 1a side, whereby the bias effect by the plate electrode 7b can be obtained closer to the reaction chamber 1a. In other words, while the electric power supplied to the plate electrode 7b is suppressed to be small, the non-volatile material adhering to the dielectric member 3 and the cover 5 can be removed easily.

The above-described structure is merely as an illustrative example, and only the electrode layer including the electric heater, or only the electrode layer including the plate electrode may be disposed on the surface of the dielectric member 3 on the reaction chamber 1a side. In contrast, the plate electrode may be provided as the first electrode pattern, and the electric heater may be provided as the second electrode pattern. In these examples, it is preferable that the first electrode pattern closer to the dielectric member 3 is the electric heater, and the second electrode pattern is the plate electrode. This is because the dielectric member 3 can be efficiently heated.

FIG. 3 is a plan view showing an example of the electric heater 6b. The electric heater 6b includes a line-shaped pattern formed of high-resistance metal. The line-shaped pattern is drawn in, for example, a serpentine-type shape. The electric heater 6b is connected to heater terminals 6a penetrating the dielectric member 3. The heater terminals 6a are electrically connected to an AC power supply 16. The AC power supply 16 supplies power to the heater terminals 6a to thereby generate heat from the first electrode pattern 6b. For example, tungsten (W) is preferably used as the high-resistance metal.

FIG. 4 is a plan view showing an example of the plate electrode 7b. The plate electrode 7b includes a planer pattern formed of a wide metal thin-film. Tungsten (W) can also be used as the plate electrode 7b. The plate electrode 7b is preferably formed, for example, to cover the electrode pattern of the electric heater and also to cover 50% or more of the reaction-chamber 1a side surface of the dielectric member 3 (i.e., the second surface). Consequently, a most part of each of the dielectric member 3 and the cover 5 can be shielded. The plate electrode 7b is provided with a plurality of slits 3s arranged radially in order to transmit radio frequency power outputted from the first radio frequency power supply 11 and the coil 4.

The plate electrode 7b is connected, near the center of the dielectric member 3, to an FS terminal 7a penetrating the dielectric member 3. The FS terminal 7a is electrically connected to a second radio frequency power supply 12. Bias voltage is generated near the second electrode pattern 7b by supplying power to the FS terminal 7a from the second radio frequency power supply 12. Accordingly, the adhesion of non-volatile material to the dielectric member 3 and the cover 5 can be suppressed.

In FIG. 1, although the coil 4 is connected to the first radio frequency power supply 11 and the second electrode layer 7 (plate electrode 7b) is connected to the second radio frequency power supply 12, the coil 4 and the plate electrode 7b may be connected in parallel to the same radio frequency power supply via a variable choke or a variable capacitor. Alternatively, the configuration of FIG. 1 may be modified in a manner that the coil 4 is connected to the first radio frequency power supply 11 and the plate electrode 7b is connected to a variable choke or a variable capacitor, whereby power oscillated from the first radio frequency power supply 11 is superimposed on the plate electrode 7b via air from the coil 4, and a ratio between power supplied to the coil 4 and power supplied to the plate electrode 7b is adjusted by the variable choke or the variable capacitor.

As shown by a dotted line in FIG. 4, the electric heater 6b is preferably disposed so as not to protrude from an outer periphery of the plate electrode 7b, as viewed from a direction perpendicular to the surface of the dielectric member 3. Consequently, a loss of radio frequency power transmitting the slits 3s can be suppressed.

Next, an example of a manufacturing method of the electrode layer 19 will be described.

At first, the dielectric member 3 of a disc shape, provided with a groove 3a on one surface (a first surface) thereof, is prepared. The dielectric member 3 has a thickness, for example, in a range of 10 to 40 mm at a portion not provided with the groove 3a.

The dielectric member 3 includes a flat portion on the surface thereof on the reaction chamber 1a side, and the electrode layer 19 is preferably formed in the flat portion. When the electrode layer 19 is formed in the flat portion of the dielectric member 3, the formation can be made by a relatively simple process, and a plurality of the electrode layers 19 can be laminated. Further, by forming the flat portion, defect such as breaking of the electrode pattern or short-circuit of the electrode pattern caused by coverage fault of the insulation film covering the electrode pattern hardly occurs. In addition, the surface of the dielectric member 3 on the reaction chamber 1a side can be made flat, and the cover 5 which covers the surface of the dielectric member 3 on the reaction chamber 1a side can also have a flat structure. Consequently, distribution of the plasma is likely to be uniform, and uniformity of etching can be improved. Further, maintainability is also improved.

The electrode layer 19 is formed on the other surface (second surface) of the dielectric member 3 in the following manner.

At first, a predetermined number of through holes are formed in the dielectric member 3. Conductor is filled or passed in the through holes to form the heater terminals 6a and the FS terminal 7a.

Next, the electric heater 6b is formed on the second surface. The electric heater 6b is formed by thermal spraying high-resistance metal such as tungsten on the second surface via a mask corresponding to the first electrode pattern. A thickness of a thermal-sprayed pattern thus formed is, for example, in a range from 10 to 300 μm. Alternatively, the electric heater may be formed by bending a tungsten wire into a shape of the first electrode pattern and thereafter fixing the tungsten wire on the second surface. In this case, the electrode pattern formed by the thermal-sprayed pattern or by means of other methods is electrically connected to the heater terminals 6a.

Next, the first insulation film 6c is formed so as to entirely cover the electric heater 6b. White alumina is preferably used as material of the first insulation film 6c. The first insulation film 6c is formed by thermal spraying white alumina on the second surface. In order to enhance adhesiveness between the dielectric member 3 and the first insulation film 6c, before thermal spraying white alumina, an adhesion layer may be formed by thermal spraying yttrium or the like on the second surface. A thickness of the first electrode layer 6 is, for example, in a range from 10 to 300 μm.

Next, the plate electrode 7b is formed on one surface of the first electrode layer 6. The plate electrode 7b is formed by thermal spraying metal on the one surface of the first electrode layer 6 via a mask corresponding to the second electrode pattern. In this case, the plate electrode 7b is formed to have the plurality of slits 3s arranged radially. A thickness of the plate electrode 7b is, for example, in a range from 10 to 300 μm. Alternatively, the plate electrode 7b may be formed by preparing a plate electrode having a shape of the second electrode pattern from a metal foil or a metal plate and thereafter fixing the plate electrode to the one surface of the first electrode layer 6. The plate electrode 7b is disposed so as to completely cover the electric heater 6b via the first insulation film 6c and is electrically connected to the FS terminal 7a.

Finally, the second insulation film 7c is formed so as to entirely cover the plate electrode 7b. White alumina is also suitable as material of the second insulation film 7c. The second insulation film 7c is formed by thermal spraying white alumina on the one surface of the first electrode layer 6. A thickness of the second electrode layer 7 is, for example, in a range from 10 to 300 μm. A method of forming the first and second insulation films is not limited to the above-described methods, and may use, for example, sputtering, chemical vapor deposition (CVD), vapor deposition, coating or the like.

According to the present embodiment, the dielectric member 3 including the electrode layer 19 can be formed by the simple method as described above. Further, the dielectric member 3 and the electrode layer 19 are formed into an integrated structure, the cover 5 can be configured by a single flat plate structure, and exchange work is easily performed.

The groove 3a is preferably formed in the surface of the dielectric member 3 outside the reaction chamber 1a so as to make the dielectric member 3 partially thin. At least a part of the coil 4 can be disposed within the groove 3a. Consequently, the part of the coil 4 disposed within the groove 3a is made closer to the reaction chamber 1a, and hence a loss of radio frequency power can be suppressed. Since the groove 3a can be formed on one surface of the plate-shaped dielectric member 3, a mechanical strength of the dielectric member 3 does not largely degrade.

According to the present embodiment, the electrode layer is formed on the surface of the dielectric member 3 on the reaction chamber 1a side, the groove 3a in which a part of the coil 4 is disposed can be formed in the surface of the dielectric member 3 outside the reaction chamber 1a. Consequently, while the adhesion of non-volatile material can be efficiently suppressed, the coil 4 can be disposed so as to suppress the loss of radio frequency power.

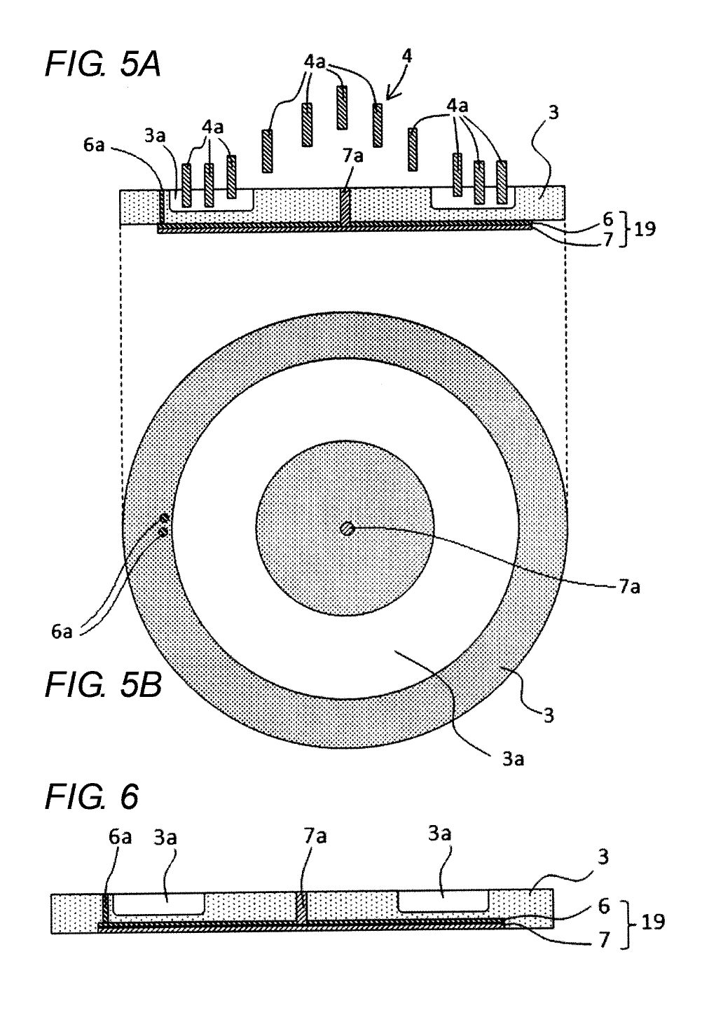

FIG. 5A schematically shows an arrangement of the dielectric member 3 and the coil 4 according to the present embodiment. The coil 4 is formed by a conductor 4a extending spirally from the center of the coil toward an outer periphery thereof as viewed from a direction perpendicular to (the surface of) the dielectric member 3. The conductor 4a may be, for example, a metal plate of a ribbon-shape or a metal line. The number of the conductor 4a forming the coil 4 is not limited to a particular number, and the shape of the coil 4 is also not limited to a particular shape. For example, the coil may be a single spiral type coil including the single conductor 4a, or a multi spiral type coil including coils formed by a plurality of conductors 4a which are connected in parallel. Further, the coil may be a plane type coil which is formed by extending the conductor 4a spirally within the same plane in parallel to the surface of the dielectric member 3, or may be a stereoscopic type coil which is formed by changing the conductor in a vertical direction with respect to the surface of the dielectric member 3 while extending the conductor 4a spirally. The coil 4 is electrically connected to the first radio frequency power supply 11 via a matching circuit (not shown). In FIG. 1 and FIGS. 5A and 5B, the coil 4 is formed such that a distance between the dielectric member 3 and the coil becomes larger at a portion in the vicinity of the center of the coil 4 than a portion in the vicinity of the outer periphery of the coil 4. However, the positional relation between the coil 4 and the dielectric member 3 is not limited thereto.

As shown in FIG. 5B, the groove 3a preferably has an annular shape which has a center which substantially overlaps with a center of the coil 4 as viewed from a direction perpendicular to the surface of the dielectric member 3. According to the arrangement, the coil 4 can be easily disposed within the groove 3a. In this respect, this feature that the center of the annular groove 3a substantially overlaps with the center of the coil 4 does not necessarily mean that the center of the groove 3a coincides with the center of the coil 4. That is, the feature that the center of the annular groove 3a is the same as the center of the coil 4 means that each of these centers resides within a circle having a radius of 100 mm as the dielectric member 3 and the coil 4 are viewed from a direction perpendicular to the surface of the dielectric member 3. In FIG. 5B, the conductor 4a is omitted for convenience.

A depth of the groove 3a is not limited to a particular size. Even if the groove 3a is shallow, effect of suppressing a loss of the radio frequency power can be obtained to some extent. In this respect, supposing that a thickness of the plate-shaped dielectric member 3 having a uniform thickness before forming the groove 3a is T, the groove 3a is preferably formed to have the maximum depth D in a range from 0.25T to 0.45T. From a viewpoint of ensuring strength, a ratio (100 s/S (%)) of an area s of the groove 3a formed in the first surface of the dielectric member 3 in plan view with respect to the entire area S of the first surface of the dielectric member 3 in plan view is preferably set to be in a range from 2 to 50%.

The groove 3a may be formed by machining, such as cutting, one of the surfaces of the dielectric member 3 having a uniform thickness and having both flat surfaces.

In order to obtain plasma with good uniformity at a surface of a substrate 15, it is preferable to generate, at the upper part within the reaction chamber 1a, plasma having a plasma density distribution (doughnut shaped distribution) higher at an outer peripheral portion than a portion in the vicinity of the center and to disperse the plasma over the surface of a substrate. Further, in order to form the plasma having the doughnut shaped distribution at the upper part within the reaction chamber 1a, a distance between the reaction chamber 1a and the coil 4 at the portion in the vicinity of the center may be set to be relatively large, whereby a coupling degree between the coil 4 and the plasma can be made low at the portion in the vicinity of the center. As a result, the center side portion of the coil 4 may not be disposed within the groove 3a. As shown in FIG. 1 and FIGS. 5A and 5B, at least the coil portion corresponding to the center of the coil 4 may be disposed completely outside of the groove 3a.

In an outer peripheral side portion of the coil 4, as the coil 4 is disposed within the groove 3a, a distance between the reaction chamber 1a and the coil 4 is made short and hence the coupling degree between the coil 4 and the plasma can be made high. Where a length of the conductor 4a forming the coil 4 is L (from a first end on a center side to a second end on an outer peripheral side), and two regions of the conductor 4a is defined as a center side portion having a length 0.5 L from the first end of the coil, and a remaining outer peripheral side portion, a ratio of the center side portion disposed within the groove 3a is preferably set to be smaller than a ratio of the remaining outer peripheral side portion disposed within the groove 3a. Further, preferably, at least the outermost peripheral portion of the coil 4 is at least partially disposed within the groove 3a. Furthermore, preferably, an outer peripheral side portion of the coil ranging from the second end (winding end) of the outermost peripheral portion to a portion of a length 0.3 L therefrom is at least partially disposed within the groove 3a.

An example of operation of the dry etching apparatus 10 according to the embodiment will be explained.

At first, atmosphere within the reaction chamber 1a is exhausted. The reaction chamber 1a contains depressurized atmosphere. A pressure almost the same as the atmospheric pressure is applied to the dielectric member 3. The dielectric member 3 has the groove 3a. A portion of the dielectric member 3 corresponding to the groove 3a has a thin thickness. In this respect, as the groove 3a is formed in the annular shape so that mechanical strength of the dielectric member 3 can be kept to a sufficient degree, the dielectric member 3 is not broken.

Thereafter, process gas is introduced into the reaction chamber 1a via the gas introduction port 8 from the predetermined gas supply source. A substrate 15 to be etched has a resist mask corresponding to an etching pattern. In a case where the substrate 15 is made of, for example, Si, fluorine-based gas (SF₆ or the like), for example, is used as the process gas. In a case where the substrate 15 is made of aluminum, for example, chlorine-based gas (HCl or the like) is used as the process gas.

Next, radio frequency power is supplied to the coil 4 from the first radio frequency power supply 11 to generate plasma within the reaction chamber 1a. At this time, bias voltage is also applied to the lower electrode 2 for holding the substrate 15, from a predetermined radio frequency power supply. Consequently, radicals or ions within the plasma are transported above the surface of the substrate 15, then accelerated by the bias voltage and collide on the substrate 15. As a result, the substrate 15 is etched.

The outer peripheral side portion with a high winding density of the conductor 4a of the coil 4 is disposed within the annular groove 3a formed in the dielectric member 3. Thus, by supplying a relatively small amount of power to the coil, doughnut-shaped high-density plasma is generated at an area near the dielectric member 3 on the reaction chamber 1a side. The plasma reaches a substrate 15 as diffusion plasma.

Power is supplied from the second radio frequency power supply 12 to the plate electrode 7b which is disposed at the surface side of the dielectric member 3 on the reaction chamber 1a side, thereby generating bias voltage near the plate electrode within the reaction chamber 1a. Thus, a part of ions within the plasma is accelerated by the bias voltage and incident on the dielectric member 3 (or the electrode layer 19) and the cover 5. As a result, adhesion of non-volatile material to the dielectric member 3 (or the electrode layer 19) and the cover 5 can be suppressed.

An etching process is performed continuously to a plurality of substrates 15. Thus, in order to secure stability of this process, power is supplied from the AC power supply 16 to the electric heater 6b provided on the reaction-chamber 1a side surface of the dielectric member 3, whereby temperature of the dielectric member 3 is managed by the heating.

### Second Embodiment

A plasma processing apparatus according to the present embodiment is the same as that of the first embodiment except that the dielectric member 3 has a recess portion which is provided on the surface on the reaction chamber 1a side (the second surface) and which has a flat bottom surface, and the electrode layer 19 is formed in the recess portion. FIG. 6 is a vertical cross-sectional view schematically showing a structure of a dielectric member 3 and an electrode layer according to the present embodiment. The recess portion is provided in a portion except for a contact region in which the second holder 18 (not shown) contacts the dielectric member 3. Respective constituent elements of this embodiment corresponding to those of the first embodiment are referred to by the common symbols.

The recess portion can be formed, for example, by machining the second surface of the dielectric member 3. A depth of the recess portion is not limited to a particular size, and may be a size to allow whole of the electrode layer 19 to be formed within the recess portion or may be a size to allow only a part of the electrode layer 19 to be formed within the recess portion. For example, the depth of the recess portion is in a range from 0.2 to 3.0 mm. The dielectric member 3 may include a protruding portion which has a flat top portion and which is provided in a portion except for the contact region in which the dielectric member 3 contacts the second holder 18. In this case, the electrode layer 19 is provided in the protruding portion.

In either case, the electrode layer 19 is formed on a flat portion of the surface of the dielectric member 3 on the reaction chamber 1a side, whereby the electrode layer 19 can be formed relatively easily. Further, breaking or short-circuit of the electrode pattern hardly occurs. In addition, the cover 5 can be configured to have a flat structure. Consequently, distribution of the plasma is likely to be uniform, and uniformity of etching can be improved.

### Third Embodiment

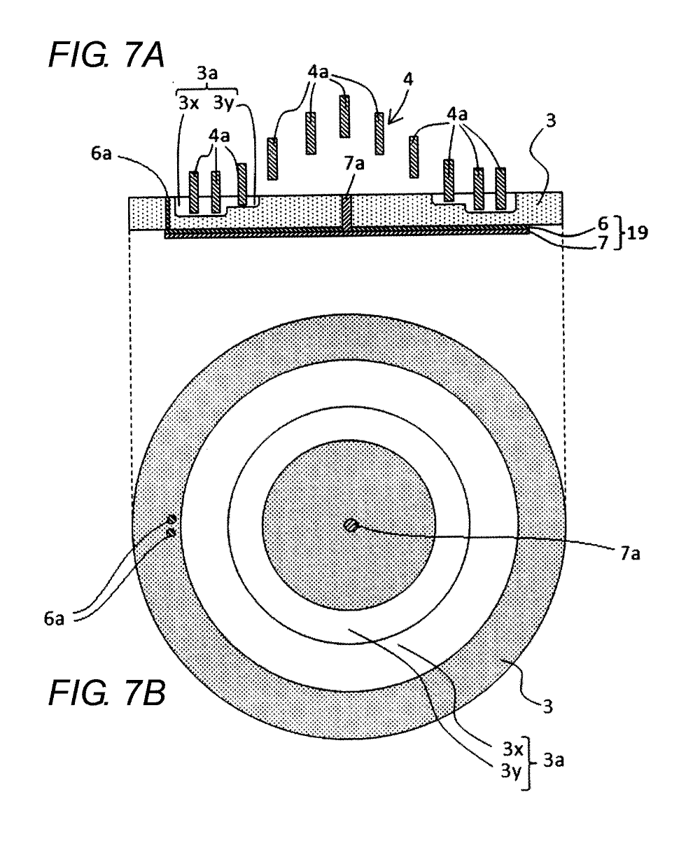

A plasma processing apparatus according to the present embodiment is the same as that of the first embodiment except for a shape of the groove of the dielectric member and a positional relation between the dielectric member and the coil. FIG. 7A is a vertical cross-sectional view schematically showing an arrangement of a dielectric member and a coil according to the present embodiment. FIG. 7B is a plan view of the dielectric member according to the present embodiment. Respective constituent elements of this embodiment corresponding to those of the first embodiment are referred to by the common symbols. In FIG. 7B, the conductor 4a is omitted for convenience.

The dielectric member 3 has a circular plate shape. An annular groove 3a is provided in the first surface of the dielectric member 3 such that a center of the annular shape of the groove 3a substantially overlaps with the center of the coil 4 in plan view. The groove 3a includes: a first groove portion 3x having a large depth, formed at an outer-side surface portion of the dielectric member; and a second groove portion 3y having a small depth, formed at an inner-side surface portion of the dielectric member. Consequently, the depth of the groove increases in two steps toward the outer side surface from the center. The coil 4 is partially disposed in both the first groove portion 3x and the second groove portion 3y. In this case, supposing that a width of the groove 3a is the same as that of the first embodiment, an average thickness of the dielectric member 3 in this embodiment is larger than that of the first embodiment. Thus, strength of the dielectric member 3 can be maintained to a larger value.

As the first groove portion 3x of the relatively large depth is disposed at the outer-side surface portion of the dielectric member and the second groove portion 3y of the relatively small depth is disposed at the inner-side surface portion of the dielectric member, a degree of inductive coupling between the coil 4 and the plasma can be increased toward the outer peripheral side of the dielectric member 3. Thus, doughnut-shaped plasma with a higher density can be generated at an area near the dielectric member 3. As a result, uniform diffusion-plasma with a higher density can be reached to a substrate 15. In a case of increasing the depth of the groove 3a toward the outer side surface from the center stepwise, the depth may be changed in three or more steps. Alternatively, the depth of the groove 3a may be increased continuously toward the outer-side surface from the center.

In FIGS. 7A and 7B, an average distance between the dielectric member 3 and the conductor of the coil 4 increases gradually toward the center from the outermost peripheral portion. In this case, the depth of the groove 3a is preferably increased stepwise or continuously toward the outer side surface from the center.

### Fourth Embodiment

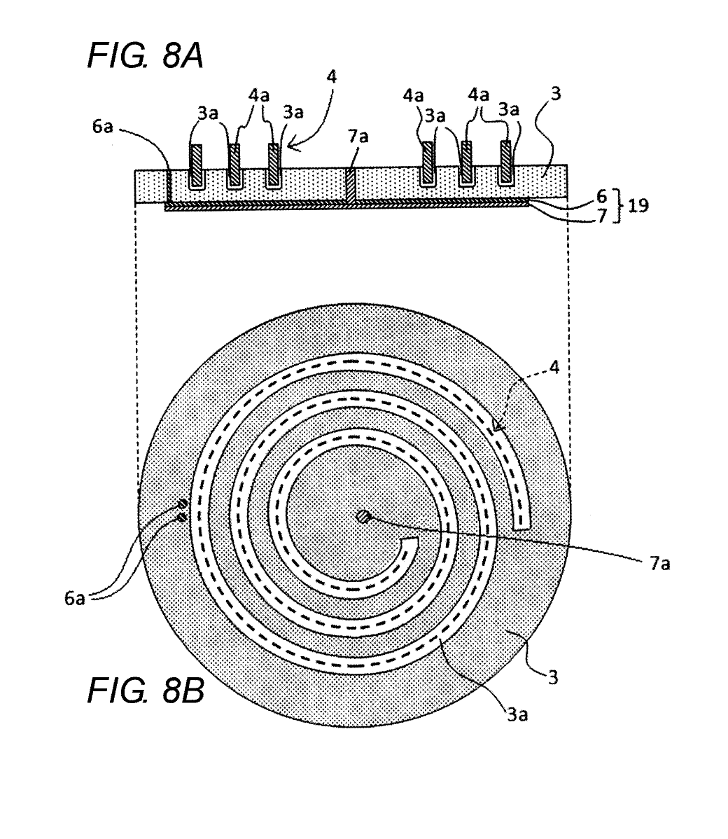

A plasma processing apparatus according to the present embodiment is the same as that of the first embodiment except for a shape of the coil, a shape of the groove of the dielectric member and a positional relation between the dielectric member and the coil. FIG. 8A is a vertical sectional view schematically showing an arrangement of a dielectric member and a coil according to this embodiment. FIG. 8B is a plan view of the dielectric member according to this embodiment. In FIGS. 8A and 8B, a position of the coil 4 is shown by a dotted line. Respective constituent elements of this embodiment corresponding to those of the first embodiment are referred to by the common symbols. In FIG. 8B, the conductor 4a is omitted for convenience.

The dielectric member 3 has a circular plate shape. A spiral-shaped groove 3a is provided in the first surface of the dielectric member 3 facing the coil 4. The conductor 4a of the coil 4 extends flatly and spirally along the groove 3a, and almost entirety of the coil 4 is disposed in the grove 3a. In a case where the coil 4 has a flat shape in this manner, the groove 3a may be shaped in correspondence with the spiral shape of the conductor 4a. Consequently, a width of the groove 3a can be made small and strength of the dielectric member 3 can be secured more easily.

Next, a plasma processing apparatus according to fifth to eleventh embodiments includes: a reaction chamber; a stage which supports an object to be processed within the reaction chamber; a cover which opposes the stage within the reaction chamber; a Faraday shield electrode which is disposed on an opposite side of the stage across the cover; a dielectric member which is disposed on the opposite side of the stage across the cover, and which closes an opening of the reaction chamber; and an induction coil which is disposed on an outer side of the dielectric member opposite to the reaction chamber. The Faraday shield electrode has at least one of a slit portion and a window portion. A gas introduction path into which material gas of plasma is introduced is formed between the cover and the dielectric member. The cover has a gas injection port which is formed in a portion opposing at least a part of the slit portion and the window portion, and through which the material gas introduced into the gas introduction path is supplied into the reaction chamber. With this configuration, change of the diameter of the gas injection port is suppressed, and the material gas can be stably supplied into the reaction chamber with a predetermined distribution. Consequently, even when the plasma processing is repeatedly performed, the object to be processed is stably etched. Further, since exchange frequency of the cover is reduced, excellent productivity can be obtained.

The cover may have a plurality of gas injection ports formed in the portion opposing at least a part of the slit portion and the window portion. By providing a plurality of gas injection ports, variation of the distribution of the material gas supplied into the reaction chamber becomes small, and uniformity of etching characteristics of the object to be processed can be more improved.

The cover may have a groove formed in the portion opposing at least a part of the slit portion and the window portion, and the gas injection port may be formed on an inner side of the groove. In this case, the cover can be placed to contact the dielectric member, and the material gas is supplied into the reaction chamber from the gas injection port via the groove formed in the cover. Consequently, the gap between the cover and the dielectric member is reduced, it is possible to suppress abnormal electrical discharge generated at the gap. Further, the etching can be performed more stably, and it is possible to easily suppress damage to the dielectric member and the cover.

The Faraday shield electrode may be disposed between the dielectric member and the cover. With this configuration, the FS electrode and the cover become closer, and it is possible to effectively suppress adhesion of non-volatile material to the cover by small electric power. In this case, the FS electrode may be formed in the surface of the dielectric member opposing the cover. The dielectric member is integrally provided with the FS electrode, whereby the structure of the plasma processing apparatus can be simplified.

In a case in which the FS electrode is provided between the dielectric member and the cover, a recess portion may be formed on a surface of the dielectric member opposing the induction coil, and at least a part of the induction coil may be disposed in the recess portion. With this configuration, the distance between the induction coil and the reaction chamber can be made smaller, and the high-density plasma can easily be made.

The Faraday shield electrode may be disposed between the dielectric member and the induction coil. In this case, the FS electrode is disposed outside the reaction chamber, whereby damage to the FS electrode due to the plasma can be suppressed.

### Fifth Embodiment

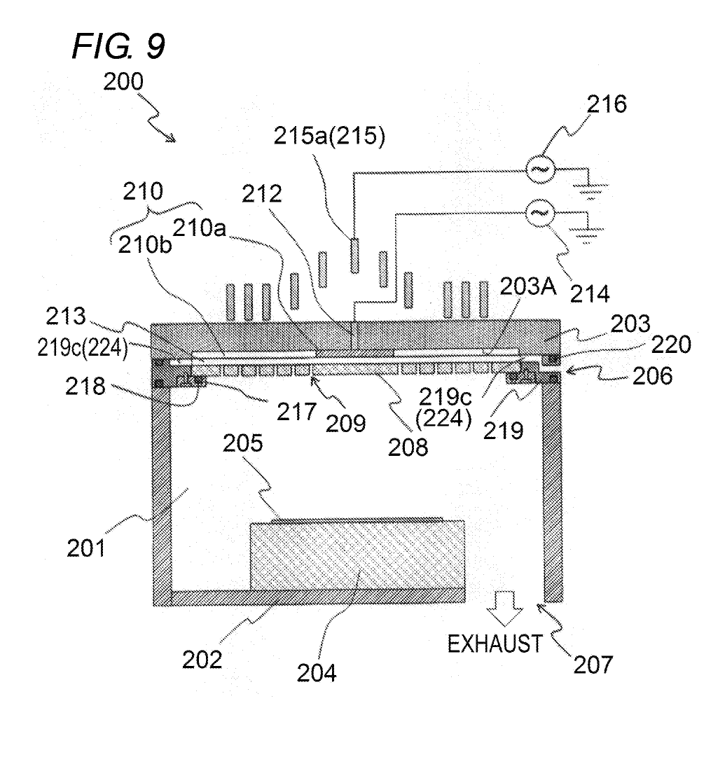

FIG. 9 shows a structure of a dry etching apparatus 200 of an inductively coupled plasma (ICP) type, which is a plasma processing apparatus according to a fifth embodiment. The dry etching apparatus 200 includes a reaction chamber 201 in which an inner atmosphere can be depressurized, a stage 204 which supports a substrate 205 as an object to be processed within the reaction chamber 201, a cover 208 which opposes the stage 204 within the reaction chamber 201, an FS electrode layer 210 which is disposed on an opposite side of the stage 204 across the cover 208, a dielectric member 203 which is disposed on an opposite side of the stage 204 across the cover 208 and which closes an opening of the reaction chamber 201, and an induction coil 215 which is disposed on an outer side of the dielectric member 203 opposite to the reaction chamber 201.

The reaction chamber 201 has a substantially cylindrical shape with an opened top portion. The opening of the top portion is closed by the dielectric member 203 as a lid, and an opening of the bottom portion is closed by a lower lid 202. The lower lid 202 is provided with a gas discharge port 207 connected to a vacuum pump (not shown). Gas, etc., in the reaction chamber 201 is exhausted from the gas discharge port 207.

The reaction chamber 201 is provided with a gate (not shown) for loading the substrate 205 into the reaction chamber 201 and unloading it therefrom. The stage 204 includes an electrode (not shown) for supplying radio frequency power to the stage 204. The stage 204 may have a function of electrostatically chucking and holding the substrate 205 and may be provided with a circulation passage of refrigerant.

A ring-shaped first holder 217 for supporting the cover 208 is supported by an upper end of a side wall of the reaction chamber 201, and the cover 208 is supported on the first holder 217 via a first elastic ring 218. An outer periphery of the cover 208 is fixed by a ring-shaped second holder 219 for supporting the dielectric member 203. The dielectric member 203 is supported on the second holder 219 via a second elastic ring 220. The cover 208 protects a major surface 203A of the dielectric member 203 on the reaction chamber 201 side from the plasma.

The reaction chamber 201, the first holder 217, the second holder 219, etc. may be formed of metallic material having sufficient rigidity such as aluminum or stainless steel (SUS), or aluminum having a surface subjected to an anodizing treatment. The dielectric member 203, the cover 208, etc. may be formed of dielectric material such as yttrium oxide (Y₂O₃), aluminum nitride (AlN), alumina (Al₂O₃), or quartz (SiO₂) may be used.

A gap is provided between the dielectric member 203 and the cover 208 to form a gas introduction path 213. The gas introduction path 213 is formed, for example, by providing a spacer between the dielectric member 203 and the cover 208, but may be formed by other configuration.

The second holder 219 is provided with a gas introduction port 206 for introducing material gas of the plasma into the reaction chamber 201 from a predetermined gas supply source. In the present embodiment, a cut portion 219c is formed in an inner periphery portion of a surface of the second holder 219 on the dielectric member 203 side, for example, to have a doughnut shape by counterboring process. The cut portion 219c communicates with the gas introduction port 206 inside the second holder 219. A gap between the cut portion 219c and the dielectric member 203 forms a gas distribution path 224. The gas introduction path 213 communicates with the gas distribution path 224.

The material gas introduced from the gas introduction port 206 passes through the gas distribution path 224 and the gas introduction path 213, and is supplied into the reaction chamber 201 through gas injection ports 209 formed in the cover 208. An amount of the material gas introduced to the gas introduction port 206 may be controlled by delivery control means (not shown) including a flow rate control device and a valve.

The induction coil 215 is provided on an outer side of the reaction chamber 201. When radio frequency power (for example, 13.56 MHz) is supplied from a first radio frequency power supply 216 to the induction coil 215, a dielectric magnetic field is generated. The dielectric magnetic field acts on the material gas in the reaction chamber 201, whereby inductively coupled plasma is generated in the reaction chamber 201. By the generated inductively coupled plasma, the substrate 205 is etched. A shape, etc. of the induction coil 215 will be described later.

The dielectric member 203 has a substantially circular plate shape in conformance with the opening shape of the reaction chamber 201, and has a thickness, for example, in a range of 10 to 40 mm. In an opposing area of the major surface 203A of the dielectric member 203 which opposes the cover 208, the given FS electrode layer 210 is formed as an FS electrode. The FS electrode layer 210 includes an electrode region 210a and a non-electrode region 210b, and the electrode region 210a is covered with an insulation film. In the present embodiment, the FS electrode layer 210 is formed between the dielectric member 203 and the cover 208, whereby the effect of removing non-volatile material adhering to the cover 208 is easily improved.

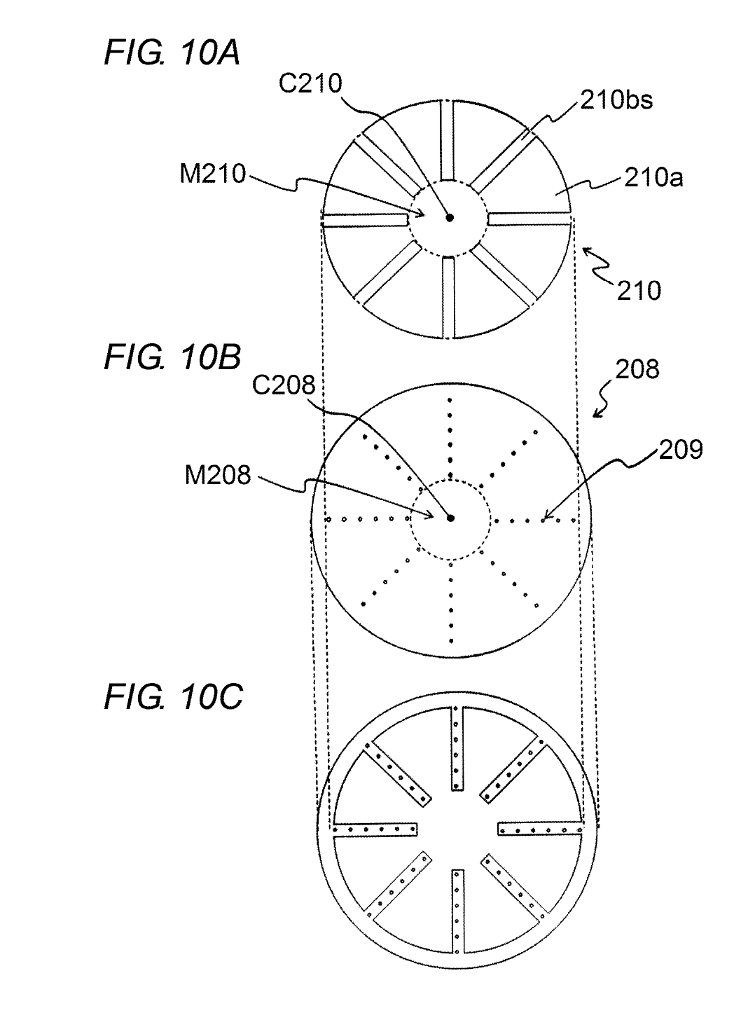

As shown in FIG. 10A, the FS electrode layer 210 has a substantially circular shape in conformance with the shape of the cover 208, and is slightly smaller than the cover 208. That is, the FS electrode layer 210 is slightly smaller than the opposing region of the dielectric member 203 opposing the cover 208. The FS electrode layer 210 is formed on the major surface 203A of the dielectric member 203 such that a center C210 of the FS electrode layer 210 overlaps with a center of the major surface 203A of the dielectric member 203. In FIG. 9 and FIG. 10A, the insulation film which covers the electrode region 210a is omitted for convenience.

The dielectric member 203 includes a flat portion in the major surface 203A, and the FS electrode layer 210 is preferably formed on the flat portion. When the FS electrode layer 210 is formed on the flat portion of the dielectric member 203, relatively simple processing such as vapor deposition or thermal spraying can be used. Further, by forming the FS electrode layer 210 on the flat portion, defect such as breaking of the electrode region 210a or short-circuit of the electrode region 210a caused by coverage fault of the insulation film covering the electrode region 210a hardly occurs. In addition, the major surface 203A after formation of the FS electrode layer 210 can be made flat, and the cover 208 disposed to oppose the major surface 203A can also have a flat structure. Consequently, distribution of the plasma is likely to be uniform, and stability of etching can be improved. Further, maintainability is also improved.

On the major surface 203A of the dielectric member 203, a plurality of electrode layers such as an electric heater layer may be laminated in addition to the FS electrode layer 210. In this case, it is preferable to form the electric heater layer on the major surface 203A of the dielectric member 203, and then to laminate the FS electrode layer 210. The laminate structure can efficiently heat the dielectric member 203 by the electric heater layer, and also increase efficiency of removing the adhering substance since a distance between the FS electrode layer 210 and the cover 208 can be reduced.

The FS electrode layer 210 may be formed in a dent having a flat bottom surface formed in the major surface 203A. The dent may be formed, for example, by machining the major surface 203A of the dielectric member 203. A depth of the dent is not limited to a particular size, and may be a size to allow whole of the FS electrode layer 210 to be formed within the dent or may be a size to allow only a part of the FS electrode layer 210 to be formed within the dent. For example, the depth of the dent is in a range from 0.2 to 3.0 mm. The dielectric member 203 may include a protruding portion which has a flat to portion and which is provided in a portion except for a contact region in which the dielectric member 203 contacts the second holder 219. In this case, the FS electrode layer 210 is provided in the protruding portion. In either case, the FS electrode layer 210 is formed on a flat portion of the major surface 203A, whereby the FS electrode layer 210 can be formed relatively easily.

The electrode region 210a is formed of conductive material such as metal. As an example of the conductive material for forming the electrode region 210a, tungsten (W) with high resistance may be used. The insulation film which covers the electrode region 210a may be formed of dielectric material such as ceramics (for example, white alumina). The insulation film covers the electrode region 210a, thereby capable of suppressing generation of metal contamination or particles caused by metal forming the electrode region 210a within the reaction chamber 201. The insulation film also suppress damage to the electrode region 210a caused by the material gas or the plasma.

The electrode region 210a is formed to have a shape so as to allow a dielectric magnetic field to pass through the electrode region 210a. The dielectric magnetic field is output from the induction coil 215 by supply of radio frequency power from the first radio frequency power supply 216. That is, the FS electrode layer 210 includes, in addition to the electrode region 210a, at least one of a slit portion 210bs and a window portion 210bw which are not provided with the electrode region 210a. As used herein, the slit portion 210bs and the window portion 210bw may be collectively referred to as the non-electrode region 210b. The non-electrode region 210b is formed, for example, by a clearance or an insulation film.

The window portion 210bw is defined as a region of the non-electrode region 210b in which an entire outer periphery is surrounded by the electrode region 210a. The slit portion 210bs is defined as a region of the non-electrode region 210b in which only a part of an outer periphery contacts the electrode region 210a.

In the present embodiment, as shown in FIG. 10A, the FS electrode layer 210 includes the electrode regions 210a and the slit portions 210bs radially extending from an outer edge of a center portion M210 of the FS electrode layer 210. The center portion M210 means, for example, where a radius of the FS electrode layer 210 is R210, an inside area of a circle having a radius of R210/4 from the center C210.

FIG. 10A shows an example in which the slit portions 210bs are formed at equal intervals, but it is not limited thereto. From a viewpoint of uniformly generating the plasma, a plurality of slit portions 210bs is preferably formed such that the slit portions 210bs are symmetric with respect to the center C210 of the FS electrode layer 210 or are symmetric with respect to a line through the center C210. The number of slit portions 210bs is not limited to a particular number, and may be set arbitrary.

In FIG. 10A, the slit portion 210bs has a rectangular shape. However, the shape of the slit portion is not limited thereto, and may be a trapezoid or triangle shape which increases its width toward the outer periphery of the FS electrode layer 210. A width of the slit portion 210bs is not limited to a particular size, but the width of the slit portion 210bs is preferably smaller than a thickness T208 of the cover 208. The thickness T208 of the cover 208 is, for example, in a range from 3 to 10 mm. Further, as described above, a gas injection port is arranged to oppose at least a part of the slit portion, and taking it into consideration, it is preferable that the width of at least a part of the slit portion 210bs opposing the gas injection port is larger than a diameter r of the gas injection port, and also preferable that an average of the width of the slit portion 210bs is larger than the diameter r of the gas injection port. The width of the slit portion 210bs means that a length in a direction perpendicular to a direction from the outer edge of the center portion M210 toward the outer periphery of the FS electrode layer 210 (this definition is applied in the following embodiments).

A total area of the non-electrode region 210b including the slit portion 210bs (or a total area of the electrode region 210a) may be set arbitrary in consideration for the electric power supplied to the FS electrode layer 210, the kind of the substance adhering to the cover 208, etc. For example, the number shape, width of the slit portion 210bs can be set such that the total area of the non-electrode region 210b including the slit portion 210bs is equal to or smaller than a half of a total area of the electrode region 210a and the non-electrode region 210b.

The FS electrode layer 210 is connected to a power feed terminal 212 which penetrate through the dielectric member 203 and is connected to a second radio frequency power supply 214. From the second radio frequency power supply 214, radio frequency power (for example, 13.56 MHz) is supplied to the FS electrode layer 210. When the radio frequency power is supplied to the FS electrode layer 210, bias voltage is generated between the plasma and the cover 208, more specifically, between the plasma and a region of the surface of the cover 208 opposing the stage 204 and located immediately below the electrode region 210a. By the bias voltage, ions in the plasma move toward the electrode region 210a, and collide on the region of the surface of the cover 208 opposing the stage 204 and located immediately below the electrode region 210a. Consequently, the substance adhering to the cover 208 such as reactive product is removed.

FIG. 9 shows an example in which the induction coil 215 is connected to the first radio frequency power supply 216, and the FS electrode layer 210 is connected to the second radio frequency power supply 214. However, the induction coil 215 and the FS electrode layer 210 may be connected in parallel to the same radio frequency power supply via a variable choke coil or a variable capacitor. Alternatively, the induction coil 215 may be connected to the first radio frequency power supply 216, and the FS electrode layer 210 may be connected to the variable choke coil or the variable capacitor, and oscillated power from the induction coil 215 supplied from the first radio frequency power supply 216 may be superimposed to the FS electrode layer 210 via air. In this case, the ratio of power between the induction coil 215 and the FS electrode layer 210 may be adjusted by the variable choke coil and the variable capacitor.

The frequency of the radio frequency power supplied from the second radio frequency power supply 214 to the FS electrode layer 210 may be different from the frequency of the radio frequency power supplied to the induction coil 215. When the frequency of the radio frequency power supplied to the FS electrode layer 210 is set to a frequency (for example, 2 MHz) different from the frequency of the radio frequency power supplied to the induction coil 215 (for example, 13.56 MHz), interference between the radio frequency supplied to the induction coil 215 and the radio frequency supplied to the FS electrode layer 210 can be suppressed, and the impedance matching in the radio frequency circuit can be stabilized.

The FS electrode layer 210 can be formed by thermal spraying or vapor depositing metal on the surface of the dielectric member 203 through a mask corresponding to the non-electrode region 210b. Consequently, the FS electrode layer 210 is formed to have a shape including a plurality of radially-arranged slit portions (the non-electrode region 210b). A thickness of the electrode region 210a is, for example, in a range from 10 to 300 μm. Alternatively, the FS electrode layer 210 having the shape of the electrode region 210a is shaped from a metal foil or a metal plate, and then the FS electrode layer 210 may be fixed to the surface of the dielectric member 203. The electrode region 210a is electrically connected to the power feed terminal 212. The power feed terminal 212 is formed by forming a predetermined number of through holes in the dielectric member 203 and then filling or inserting conductor in the through hole.

The insulation film which covers the electrode region 210a is formed, for example, by thermal spraying white alumina on the surface of the electrode region 210a. A thickness of the FS electrode layer 210 including the insulation film is, for example, in a range from 10 to 300 μm. A method for forming the insulation film is not limited to thermal spraying, but may be, for example, sputtering, chemical vapor deposition (CVD), vapor deposition, coating, etc. In this case, the insulation film may be formed by thermal spraying on the entire surface of the FS electrode layer 210 including the non-electrode region 210b, whereby the electrode region 210a covered with the insulation film can be formed simultaneously with the non-electrode region 210b formed by the insulation film. The non-electrode region 210b is not necessarily formed by the insulation film, and may simply be formed by a clearance.

The FS electrode layer 210 formed by the above-described method is formed into a structure integrated with the dielectric member 203. Consequently, the major surface 203A of the dielectric member 203 after formation of the FS electrode layer 210 can be formed to have a flat or nearly flat shape. The cover 208 disposed adjacent to the dielectric member 203 can be configured by a single flat plate structure. Consequently, distribution of the plasma is likely to be uniform, and stability of etching can be improved. Further, maintainability is also improved.

The cover 208 has a function of protecting the dielectric member 203 from the plasma, and also a function of supplying the material gas to the reaction chamber 201. That is, in the cover 208, the gas injection port 209 is formed to penetrate the cover 208 in a thickness direction thereof.

As shown in FIG. 10B, the gas injection port 209 is formed at a position opposing at least a part of the slit portion 210bs of the FS electrode layer 210. In other words, when the FS electrode layer 210 and the cover 208 provided in the plasma processing apparatus are viewed from the FS electrode layer 210 side, as shown in FIG. 10C, the gas injection port 209 is disposed so as not to overlap with the electrode region 210a. However, not all of the gas injection ports 209 may be disposed so as not to overlap with the electrode region 210a. For example, equal to or more than 90% of the gas injection ports may be disposed so as not to overlap with the electrode region 210a.

When the radio frequency power is supplied to the FS electrode layer 210, bias voltage is generated at the region of the surface of the cover 208 opposing the stage and located immediately below the electrode region 210a. By the bias voltage, ions in the plasma are incident on the cover 208. As a result, the adhering substance adhering to the cover 208 is removed. In contrast, since the gas injection ports 209 are disposed in a region except for a region immediately below the electrode region 210a (i.e., the gas injection ports 209 are disposed in the non-electrode region 210b), even when the radio frequency power is supplied to the FS electrode layer 210, bias voltage is hardly generated in the vicinity of the gas injection ports 209. Consequently, a few ions in the plasma is incident on the gas injection ports 209, and opening edges of the gas injection ports 209 on the stage side is hardly etched.

As described above, the gas injection port 209 is disposed so as not to overlap with the electrode region 210a and so as to oppose a part of the slit portion 210bs and the window portion 210bw, whereby increase of the diameter of the gas injection port 209 or change of the shape of the gas injection port 209 can be suppressed. Consequently, the material gas can be supplied the reaction chamber 201 stably with a predetermined distribution, and etching can stably progress. Further, since deformation of the gas injection ports 209 is suppressed, exchange frequency of the cover 208 is reduced.

In order to form a portion with high bias voltage and a portion with low bias voltage on the cover 208 as described above, it is preferable that the electrode region 210a is close to the cover 208. A preferable distance between the electrode region 210a and the cover 208 is, for example, in a range from about 5 mm to about 12 mm. As the distance between the cover 208 and the electrode region 210a becomes smaller, the distribution of bias voltage generated on the surface of the cover 208 becomes closer to a shape obtained by transferring the shape of the electrode region 210a when the radio frequency power is supplied to the electrode region 210a. Consequently, contrast of intensity of the bias voltage in the region of the cover 208 immediately below the electrode region 210a and in the non-electrode region 210b can be clear.

Further, according to the embodiments of the present invention, advantages other than the above-described advantages can be obtained.

In order to supply the material gas into the reaction chamber through the gas injection port provided in the cover, the material gas has to be forced from the gas injection port at a pressure higher than internal pressure of the reaction chamber (normally, about in a range from 1 to 50 Pa). Consequently, high pressure, for example, 100 Pa or more, is locally applied to a portion in the vicinity of the gas injection port. Further, generally, electric field is likely to be concentrated to an angular portion such as the opening edge of the gas injection port. That is, during the etching process, the portion in the vicinity of the gas injection port is likely to be under a state of high pressure and high electric field. As a result, abnormal electrical discharge may occur in the vicinity of the gas injection port. Further, in a case in which the FS electrode is provided in the vicinity of the cover and in the reaction chamber in order to increase the effect of removing the adhering substance of the cover, electric field is generated by the FS electrode in the vicinity of the cover. That is, the abnormal electrical discharge is more likely to occur in the vicinity of the gas injection port. Accordingly, the gas injection port provided in the cover may be a cause of the abnormal electrical discharge, and has been one of constraints on improvement of the adhering substance removal effect by the FS electrode.

In contrast, in order to perform uniform etching, it is beneficial to provide a plurality of gas injection ports in the cover so as to shower the substrate with the gas from above the reaction chamber.

According to the embodiments of the present invention, the gas injection port 209 is disposed so as not to overlap with the electrode region 210a and to oppose at least a part of the slit portion 210bs and the window portion 210bw of the cover 208, whereby it is possible to resolve trade-off between the adhering substance removal effect of the FS electrode layer 210 and the improvement of etching uniformity. In other words, by providing the gas injection port 209 in the cover 208, uniform etching characteristics can be obtained, and the adhering substance removal effect of the FS electrode layer 210 can be improved.

As shown in FIG. 10B, the gas injection ports 209 are radially arranged at equal intervals from the outer edge of the center portion M208 of the cover 208 toward the outer periphery of the cover 208 so as to correspond to at least a part of the slit portion 210bs. The arrangement of the gas injection ports 209 is not limited thereto, and the gas injection ports 209 may be arranged at random at positions corresponding to at least a part of the slit portion 210bs. In other words, the gas injection ports 209 may be arbitrarily arranged at positions such that the distribution of the plasma generated in the reaction chamber 201 can be uniform. The center portion M208 of the cover 208 means, for example, where a radius of the cover 208 is R208, an inside area of a circle having a radius of R208/4 from the center C208.

The shape of the gas injection port 209 is not limited to a particular shape, and may be a circle, an ellipse, a rectangle, a rounded rectangle, etc. Particularly, the circle is preferable since it can be formed easily. The number of gas injection ports 209 is not limited to a particular number, and may be arbitrarily set in accordance with the shape or size of the gas injection ports 209. Particularly, the number of the gas injection ports 209 is preferably a plural number since the distribution of the material gas is controlled easily. For example, when the gas injection port 209 has a circular shape and has a diameter r in a range from 0.1 to 1.5 mm, the number of the gas injection ports 209 is preferably in a range from 48 to 60. Further from a viewpoint of supply of a sufficient amount of the material gas required for etching from the gas injection ports 209 into the reaction chamber 201, the total area of the gas injection ports 209 is in a range from 0.5 to 5% of the area of the major surface 203A of the cover 208.

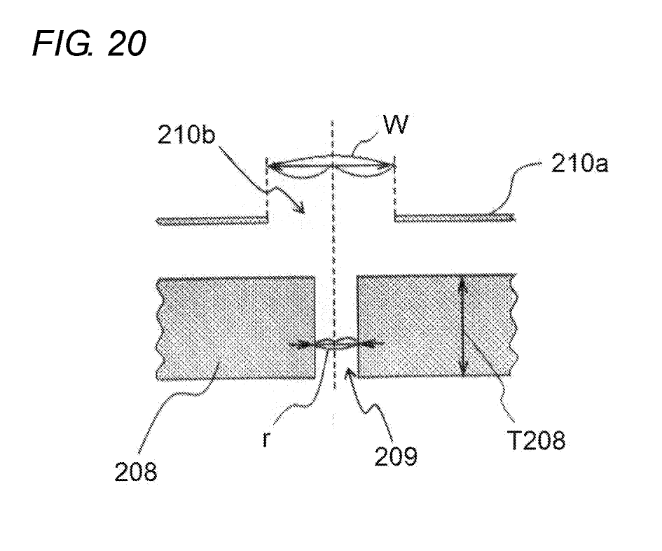

The width of the slit portion 210bs can be arbitrarily set in accordance with the electric power supplied to the FS electrode layer 210, etc. as described above. Particularly, from a viewpoint of ability of supply of the material gas by the gas injection port 209 and ability of generation of bias voltage by the FS electrode layer 210, in a case in which one gas injection port 209 is provided in a width direction of the slit portion 210bs, a diameter r of the gas injection port 209 and the average width W of the slit portion 210bs preferably satisfy a relationship r≦W≦T208 where T208 is a thickness of the cover 208 (see FIG. 20). Further, a center of the gas injection port 209 is preferably located on a straight line which divides the width of the slit portion 210bs in half.

The diameter r of the gas injection port 209 is not limited to a particular size, but preferably in a range from 0.1 to 1.5 mm, more preferably in a range from 0.3 to 1.0 mm, and especially preferably in a range from 0.5 to 0.8 mm, from a viewpoint of ease of formation and ability of supply of the material gas. The thickness T208 of the cover 208 is not limited to a particular size, and may be set arbitrarily according to desired bias voltage. The thickness T208 of the cover 208 is preferably in a range from 3 to 15 mm, and more preferably in a range from 5 to 12 mm, and especially preferably in a range from 6 to 10 mm.

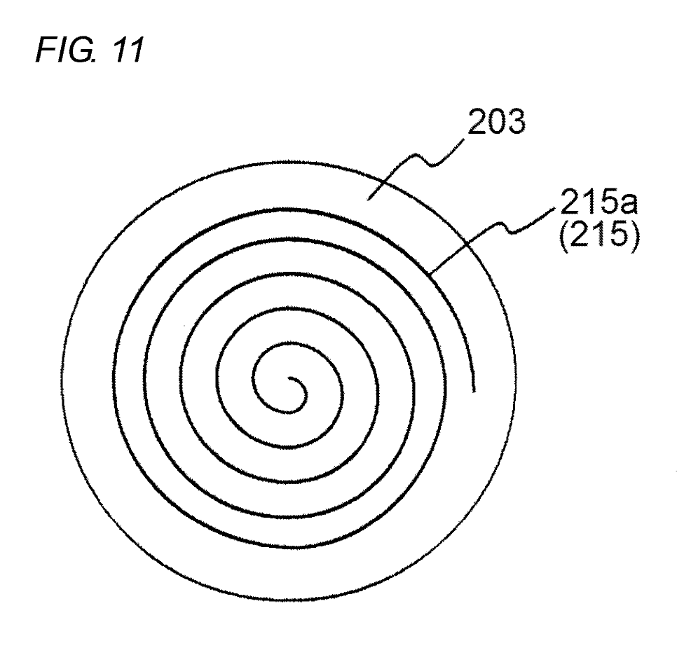

FIG. 11 shows an arrangement of the dielectric member 203 and the induction coil 215 according to the present embodiment. FIG. 11 is a plan view of the induction coil 215 as viewed from a direction of a normal line of the major surface 203A of the dielectric member 203 on the outer side of the reaction chamber 201.

The induction coil 215 is formed by a conductor 215a extending spirally from the center of the coil toward an outer periphery thereof. The conductor 215a may be, for example, a metal plate of a ribbon-shape or a metal line. The number of the conductor 215a forming the induction coil 215 is not limited to a particular number, and the shape of the induction coil 215 is also not limited to a particular shape. For example, the induction coil 215 may be a single spiral type coil including the single conductor 215a, or may be a multi spiral type coil including coils formed by a plurality of conductors 215a which are connected in parallel.

Further, the induction coil 215 may be a plane type coil which is formed by extending the conductor 215a spirally within the same plane I parallel to the surface of the dielectric member 203, or may be a stereoscopic type coil which is formed by pulling the conductor 215a in the direction of the normal line of the major surface 203A of the dielectric member 203 on the outer side of the reaction chamber 201 while extending the conductor 215a spirally from an outside to an inside. The induction coil 215 is electrically connected to the first radio frequency power supply 216 via a matching circuit (not shown), etc. In FIG. 9, the induction coil 215 is formed such that a distance between the dielectric member 203 and the induction coil 215 becomes larger at a portion in the vicinity of the center of the induction coil 215 than a portion in the vicinity of the outer periphery of the induction coil 215. However, the positional relation between the induction coil 215 and the dielectric member 203 is not limited thereto.

An example of operation of the dry etching apparatus 200 according to the present embodiment will be explained with reference to FIG. 9.

At first, atmosphere within the reaction chamber 201 is exhausted. The reaction chamber 201 contains depressurized atmosphere. A pressure substantially the same as the atmospheric pressure is applied to the dielectric member 203.

Thereafter, the material gas is supplied into the reaction chamber 201 from a predetermined gas supply source via the gas introduction port 206, the gas introduction path 213 and the gas injection ports 209. The substrate 205 to be etched has a resist mask corresponding to an etching pattern. The substrate 205 may be made of, for example, semiconductor material such as silicon (Si) or gallium arsenic (GaAs), metal material such as aluminum, gold or platinum, or non-volatile material such as ferroelectric material, noble metal material or magnetic material. In a case in which the substrate 205 is made of, for example, Si, fluorine-based gas (SF₆ or the like), for example, is used as the material gas. Further, in a case in which the substrate 205 is made of, for example, the metal material or the non-volatile material, chlorine-based gas (BCl₃, Cl₂ or the like), for example, is used as the material gas.

Next, radio frequency power is supplied from the first radio frequency power supply 216 to the induction coil 215 to generate doughnut-shaped high-density plasma in the vicinity of the electric member 203 on the reaction chamber 201 side. At this time, bias voltage is also applied to the stage for holding the substrate 205 from the predetermined radio frequency power supply. Consequently, radicals or ions within the plasma are transported above the surface of the substrate 205, then accelerated by the bias voltage and collide on the substrate 205. As a result, the substrate 205 is etched.

On the other hand, radio frequency power is supplied to the FS electrode layer 210 from the second radio frequency power supply 214, and bias voltage is generated in the vicinity of the electrode region 210a. Consequently, a part of ions within the plasma is accelerated by the bias voltage, and collide on the region on the surface of the cover 208 opposing the stage 204 and located immediately below the electrode region 210a. As a result, the substance adhering to the cover 208 such as reactive product is removed.

### Sixth Embodiment

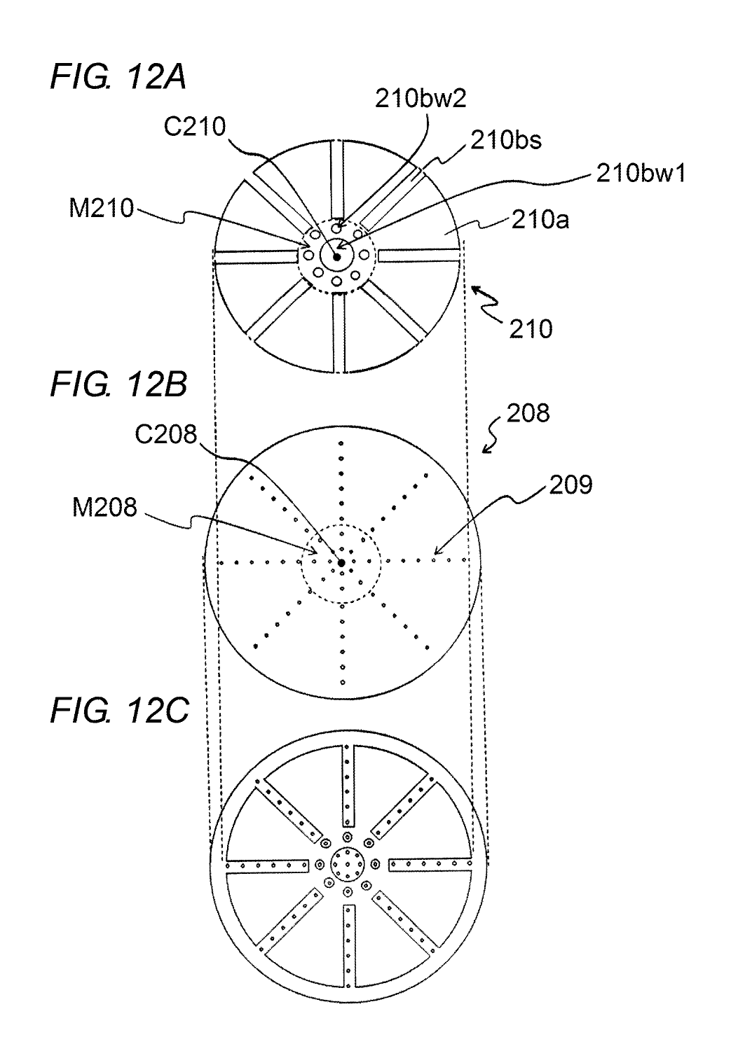

A plasma processing apparatus according to the present embodiment is the same as that of the fifth embodiment except that the non-electrode region 210b in the FS electrode layer 210 includes a window portion and a slit portion. FIGS. 12A to 12C are a top views schematically showing structure of the FS electrode layer and the cover 208 according to the present embodiment. Respective constituent elements of this embodiment corresponding to those of the fifth embodiment are referred to by the common symbols.

The non-electrode region 210b includes a slit portion 21bs radially extending from an outer edge of the center portion M210 of the dielectric member 203 and a window portion 210bw formed in the center portion M210. A shape of the window portion 210bw is not limited to a particular shape, and may be a circle, a rectangle or a combination thereof.

A size of the window portion 210bw is not limited to a particular size. For example, the size, the number, etc. of window portion 210bw may be arbitrarily set such that a total area of the non-electrode region 210b including the slit portion 210bs and the window portion 210bw is equal to or less than 50% of a total area of the electrode region 210a and the non-electrode region 210b. Particularly, the gas injection port is disposed to oppose at least a part of the window portion, and taking it into consideration, the window portion 210bw preferably has a size in which at least one gas injection port can be formed.

In FIG. 12A, there are formed a large-diameter window portion 210Bw1 including the center C210 of the FS electrode layer 210 and a plurality of small-diameter window portion 210bw2 surrounding the window portion 210bw1. However arrangement of the window portions is not limited thereto. In FIG. 12A, the window portion 210bw1 has a size in which nine gas injection ports 209 can be formed, and the window portion 210bw2 has a size in which one gas injection port 209 can be formed.

The diameter of the window portion 210bw can be set arbitrarily in accordance with the electric power supplied to the FS electrode layer 210 as described above. Particularly, from a viewpoint of ability of supply of the material gas by the gas injection port 209 and ability of generation of bias voltage by the FS electrode layer 210, in a case in which one circular gas injection port 209 is disposed in a window portion having a size in which one gas injection port 209 can be formed, a diameter r of the gas injection port 209 and a diameter W of the window portion 210bw are preferably satisfy a relationship r≦W≦T208 where T208 is a thickness of the cover 208 (see FIG. 20).

As shown in FIG. 12B, the gas injection port 209 is also formed in the center portion M208 of the cover 208. Consequently, the material gas can be distributed in the vicinity of the center of the reaction chamber 201. FIG. 12C shows a plan view of the FS electrode layer 210 and the cover 208 provided in the plasma processing apparatus as viewed from the FS electrode layer 210 side. The gas injection port 209 formed in the center portion M208 of the cover 208 is also arranged to oppose the non-electrode region 210b (the window portion 210bw1 and the window portion 210bw2).

### Seventh Embodiment

A plasma processing apparatus according to the present embodiment has a groove 208a in a portion of a major surface 208A of the cover 208 opposing the dielectric member 203 and located to oppose at least a part of the non-electrode region 210b (the slit portion and/or the window portion). The groove 208a has the gas injection port 209. In other words, an opening end portion of the gas injection port 209 on the dielectric member 203 side is formed within the groove 208a, and the gas injection ports 209 penetrate from the opening end portion to the other major surface 208B of the cover 208. Not all of the grooves 208a may oppose to the non-electrode region 210b (the slit portion and/or the window portion).

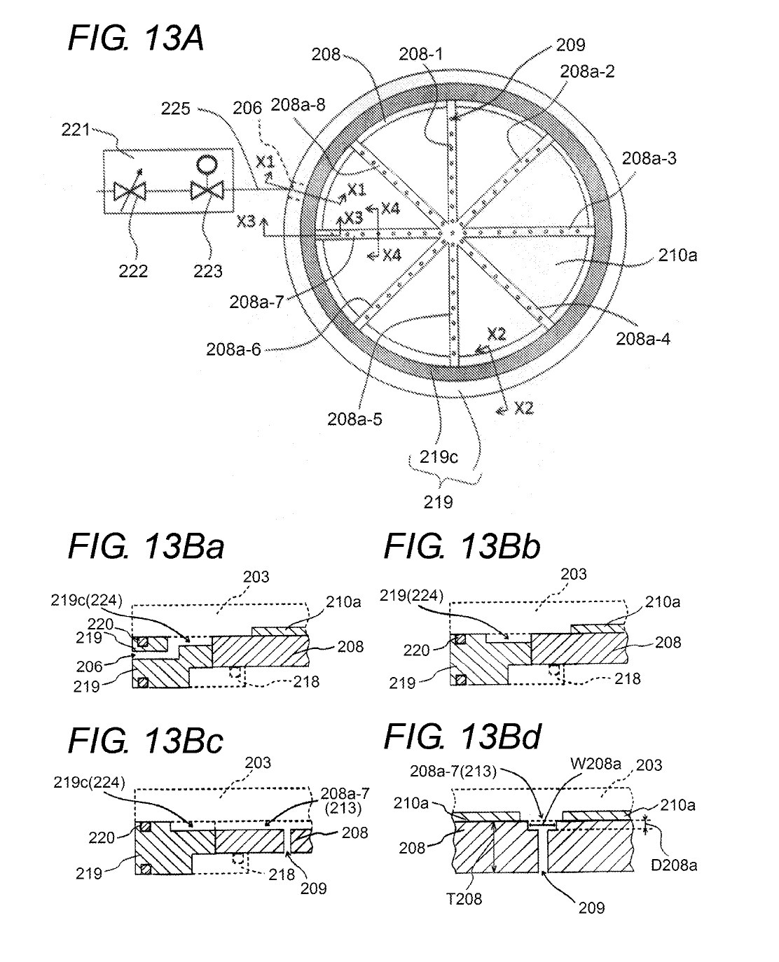

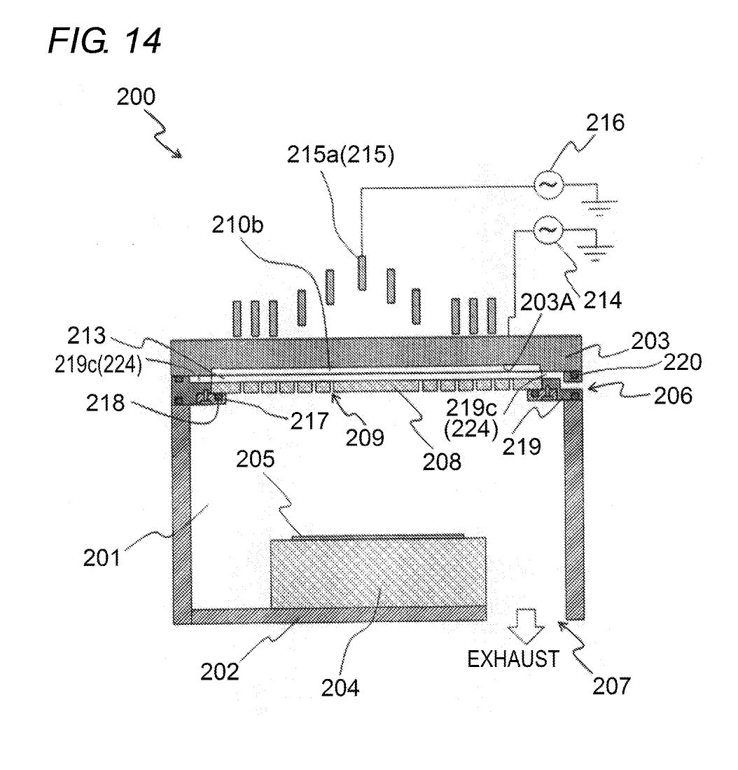

FIG. 13A is a top view schematically showing a structure of the cover and the second holder according to the present embodiment, and FIGS. 13Ba, 13Bb, 13Bc and 13Bd are enlarged cross-sectional views cut along lines X1-X1, X2-X2, X3-X3 and X4-X4 shown in FIG. 13A, respectively. In FIGS. 13Ba to 13Bd, the insulation film which covers the electrode region 210a is omitted for convenience. FIG. 14 is a cross-sectional view schematically showing a structure of the plasma processing apparatus according to the present embodiment. Respective constituent elements of this embodiment corresponding to those of the sixth embodiment are referred to by the common symbols.

The groove 208a includes a plurality of grooves 208a-1 to 208a-8 formed to radially extending from the center C208 of the cover 208 toward the outer periphery of the cover 208. The grooves 208a-1 to 208a-8 communicate with one another in the vicinity of the center C208. The grooves 208a-1 to 208a-8 also communicate with the cut portion 219c formed on an inner peripheral side of the surface of the second holder 219 on the dielectric member 203 side (see FIG. 13Bc). The cut portion 219c and the gas introduction port 206 communicate with each other inside the second holder 219 (see FIG. 13Ba). The gap between the cut portion 219c and the dielectric member 203 forms the gas distribution path 224 which surrounds an entire outer circumference edge of the cover 208. FIG. 13A shows the cut portion 219c by hatching.

The gas introduction port 206 is connected to a gas pipe 225 for supplying the material gas. The material gas introduced from the gas pipe 225 to the gas introduction port 206 is distributed via the gas distribution path 224 surrounding the entire outer circumference edge of the cover 208, and flows through outer peripheral end portions of the grooves 208a-1 to 208a-8 into the grooves 208a-1 to 208a-8 (see FIGS. 13Bc and 13Bd). Subsequently, the material gas flows into the gas injection ports 209 from the opening end portions of the gas injection ports 209 on the dielectric member 203 side respectively formed on an inner side (in bottom portions) of the grooves 208a-1 to 208a-8, and then is supplied into the reaction chamber 201.

As described above, the cut portion 219c is formed in the second holder 219, whereby the material gas can be supplied from the gas introduction ports 206 to the grooves 208a-1 to 208a-8 with relatively simple structure without complicating the pipe. An amount of the material gas introduced to the gas introduction port 206 can be controlled by delivery control means 221 including a flow rate control device 222 and a valve 223.

A width W208a of the groove 208a is not limited to a particular size, and may be sufficient to have a size in which at least one gas injection port 209 can be formed. A depth D208a of the groove 208a is also not limited to a particular size, but is preferably in about a range from 0.1 to 1 mm from in which the material gas can easily be introduced and abnormal electrical discharge hardly occurs in the gas introduction path. FIG. 13A shows an example in which the gas injection ports 209 are arrayed at interval along a line in the bottom portion of the groove 208a, but the present invention is not limited thereto. The gas injection ports 209 may be arranged along a plurality of lines in the bottom bottom portion of the groove 208a, or may be arranged at random. The gas injection ports 209 may be arbitrarily disposed as long as the distribution of the plasma generated within the reaction chamber 201 can be uniform.

As shown in FIG. 13B, in the plasma processing apparatus according to the present embodiment, the gas introduction path 213 is formed between the dielectric member 203 and the groove 208a of the cover 208. That is, a portion of the major surface of the cover 208 except for the groove 208a can contact the dielectric member 203, whereby it is possible to suppress abnormal electrical discharge caused by existence of a gap between the cover 208 and the dielectric member 203. Consequently, it is possible to easily suppress damage to the electrode region 210a.

### Eighth Embodiment

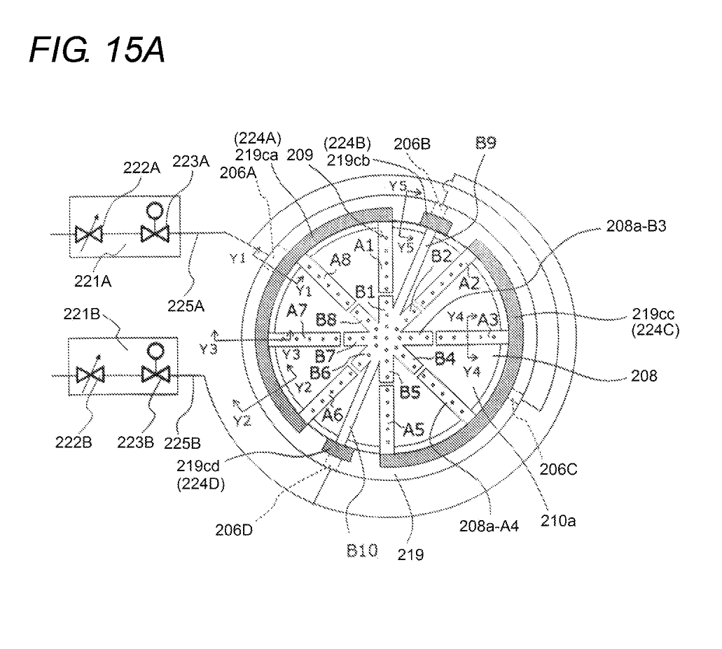

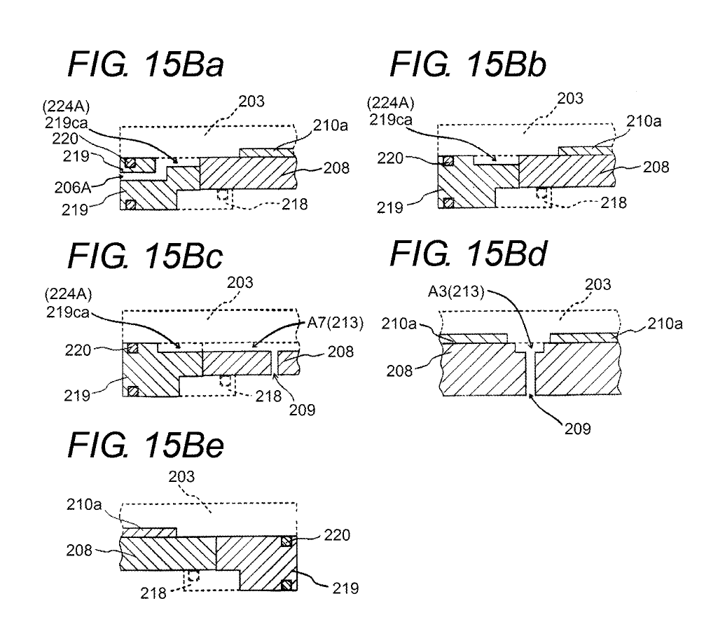

As shown in FIG. 15A, in a plasma processing apparatus according to the present embodiment, the groove 208a includes a groove 208a-A formed to radially extending from an outer edge of the center portion M208 of the cover 208 toward the outer periphery of the cover 208, and a groove 208a-B which does not communicate with the groove 208a-A. Similar to the seventh embodiment, the groove 208a includes the gas injection port 209. The material gas is supplied to the groove 208a-A and the groove 208a-B from different gas pipes 225A, 225B.

FIG. 15A is a top view schematically showing a structure of the cover and the second holder according to the present embodiment. FIGS. 15Ba, 15Bb, 15Bc, 15Bd and 15Be are enlarged cross-sectional views cut along lines Y1-Y1, Y2-Y2, Y3-Y3, Y4-Y4 and Y5-Y5 shown in FIG. 15A, respectively. In FIG. 15B, the insulation film covering the electrode region 210a is omitted for convenience. Respective constituent elements of this embodiment corresponding to those of the seventh embodiment are referred to by the common symbols.

The groove 208a-A includes grooves 208a-A1 to 208a-A8, and the grooves 208a-A1 to 208a-A8 do not directly communicate with one another. The groove 208a-B includes grooves 208a-B1 to 208a-B10, and the grooves 208a-B1 to 208a-B10 communicate with one another in the vicinity of the center C208 of the cover 208. The grooves 208a-B1 to 208a-B8 are formed to radially extend in the center portion M208 of the cover 208, and do not communicate with the groove 208a-A. The grooves 208a-B9 and 208-B10 are formed to extend from the center C208 (not shown) of the cover 208 toward the outer periphery of the cover 208. The grooves 208a-B9 and 208-B10 communicate with the gas distribution paths 224B and 224D, respectively, but do not communicate with the groove 208a-A. The grooves 208a-B1 to 208a-B8 do not directly communicate with the gas distribution paths 224B and 224D.

In the present embodiment, four gas introduction ports 206A, 206B, 206C, 206D are formed in the second holder 219. The gas introduction ports 206A, 206C are connected to the gas pipe 225A, and the gas introduction ports 206B, 206D are connected to the gas pipe 225B.

The cut portions 219c (219ca, 219cb, 219cc, 219cd) are formed on an inner periphery portion of the surface of the second holder 219 on the dielectric member 203 side (see FIGS. 15Ba to 15Bc). The cut portions 219ca, 219cb, 219cc, 219cd do not communicate with one another. The cut portions 219c (219ca, 219cb, 219cc, 219cd) communicate with the gas introduction ports 206 (206A, 206B, 206C, 206D), respectively, inside the second holder 219 (see FIG. 15Ba). The gaps formed between the cut portions 219c and the dielectric member 203 form four gas distribution paths (224A, 224B, 224C, 224D). FIG. 15A shows the cut portions 219c (219ca, 219cb, 219cc, 219cd) by hatching.

The gas distribution path 224A communicates with the grooves 208a-A1, 208a-A6, 208a-A7, and 208a-A8, and the gas distribution path 224C communicates with the grooves 208a-A2, 208a-A3, 208-A4 and 208-A5. The gas distribution path 224B communicates with the groove 208a-B9, and the gas distribution path 224D communicates with the groove 208a-B10.

The material gas supplied from the gas pipe 225A is introduced from the gas introduction ports 206A and 206C, distributed via the gas distribution paths 224A and 224C, and flows through outer peripheral end portions of the grooves 208a-A1, 208a-A6, 208a-A7 and 208a-A8 and outer peripheral end portions of the grooves 208a-A2, 208a-A3, 208a-A4 and 208a-A5 into the respective grooves 208a-A1 to 208a-A8. Subsequently, the material gas flows into the gas injection ports 209 from the opening end portions of the gas injection ports 209 on the dielectric member 203 side respectively formed on an inner side (in bottom portions) of the grooves 208a-A1 to 208a-A8, and then is supplied into the reaction chamber 201.

The material gas supplied from the gas pipe 225B is introduced from the gas introduction ports 206B and 206D, and flows into the groove 208a-B9 and the groove 208a-B10 via the gas distribution paths 224B and 224D. The material gas flowing into the grooves 208a-B9 and 208a-B10 flows into the grooves 208a-B1 to 208a-B8 communicating with one another in the vicinity of the center C208. Subsequently, the material gas flows into the gas injection ports 209 from the opening end portions of the gas injection ports 209 on the dielectric member 203 side respectively formed on an inner side (in bottom portions) of the grooves of the grooves 208a-B1 to 208a-B8, and then is supplied into the reaction chamber 201. For convenience, FIG. 15A shows the grooves 208a-A1 to 208a-A3 and 208a-A5 to 208a-A8 are simply indicated by symbols A1 to A3 and A5 to A8, respectively, and the grooves 208a-B1, 208a-B2 and 208a-B4 to 208a-B10 are simply indicated by symbols B1, B2 and B4 to B10, respectively.

As described above, the cut portion 219c is formed in the second holder 219, whereby the material gas can be supplied to the grooves 208a-A1 to 208a-A8 and the grooves 208a-B1 to 208a-B10 separately, with relatively simply structure without complicating the pipe.

An amount of the material gas supplied from the gas pipe 225A can be controlled by delivery control means 221A including a flow rate control device 222A and a valve 223A. An amount of the material gas supplied from the gas pipe 225B can be controlled by delivery control means 221B including a flow rate control device 222B and a valve 223B. The flow rate control devices 222A and 222B may include independent control mechanisms, respectively. Consequently, the distribution of the material gas can be adjusted individually at the center portion of the reaction chamber 201 and at the remaining portion of the reaction chamber 201. As a result, the distribution of the plasma generated in the reaction chamber 201 can be made uniform, which can easily make the distribution in the surface during the etching process.

### Ninth Embodiment

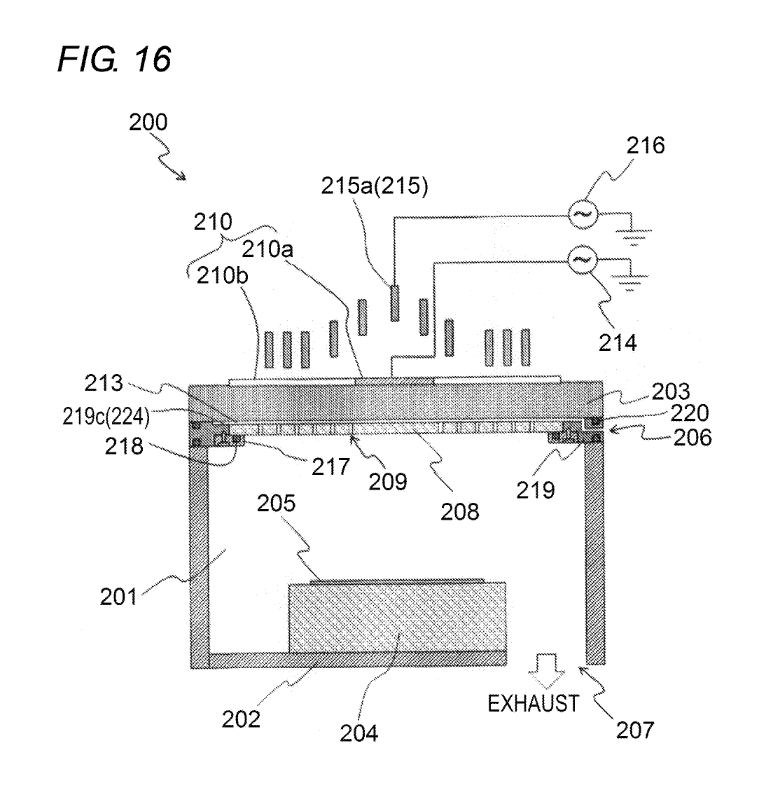

A plasma processing apparatus according to the present embodiment is the same as that of the fifth embodiment except that the FS electrode layer 210 is formed between the dielectric member 203 and the induction coil 215, i.e., on the major surface 203A of the dielectric member 203 on the induction coil 215 side. FIG. 16 is a cross-sectional view schematically showing a structure of the plasma processing apparatus. Respective constituent elements of this embodiment corresponding to those of the fifth embodiment are referred to by the common symbols.

In this structure, the gas injection port 209 is also disposed to oppose at least a part of the non-electrode region 210b, whereby change of the diameter and shape of the gas injection ports 209 is suppressed. Consequently, the material gas can be supplied into the reaction chamber with a predetermined distribution, and etching can stably progress. Further, since deformation of the gas injection port 209 is suppressed, exchange frequency of the cover 208 is reduced. Further, the FS electrode layer 210 is disposed outside the reaction chamber 201, whereby damage to the FS electrode layer 210 due to the plasma can be suppressed. In this case, the electrode region 210a is not necessarily covered with the insulation layer, and metal may be exposed. Further, the non-electrode region 210b is not necessarily formed by the insulation layer, and may be a formed by a clearance.

### Tenth Embodiment

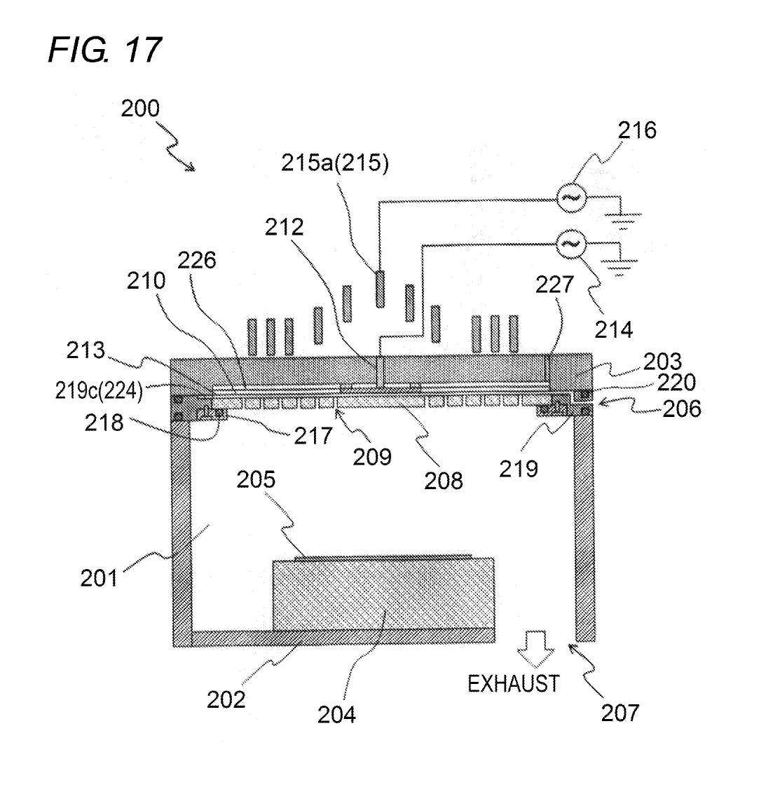

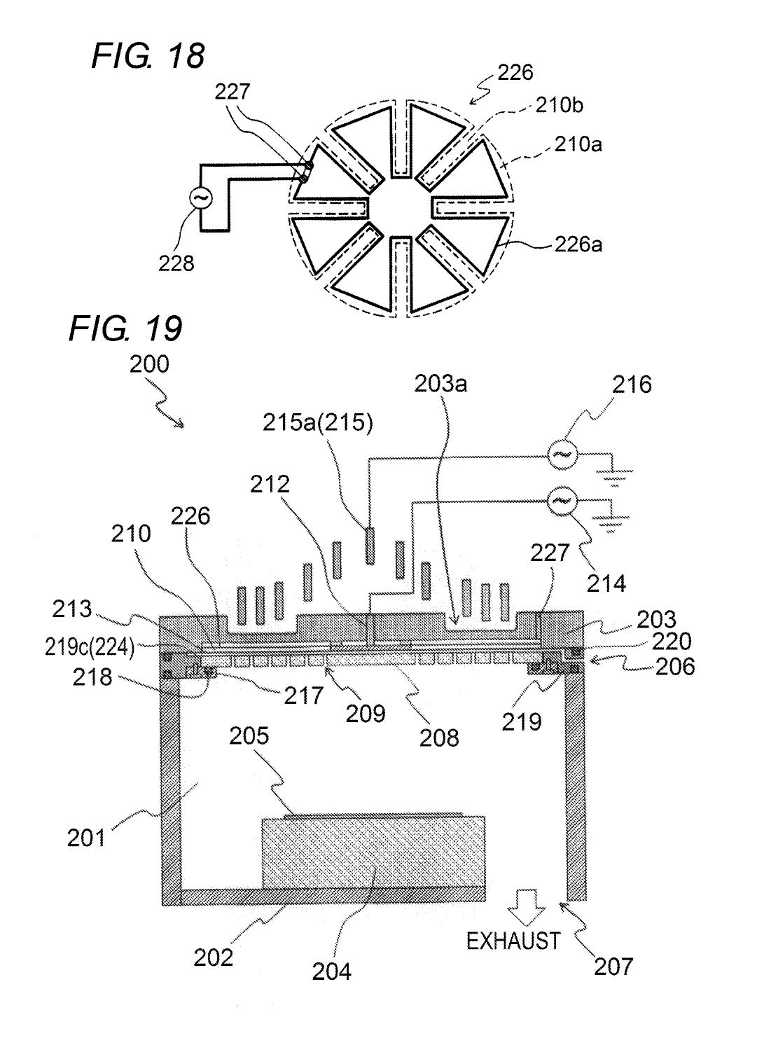

A plasma processing apparatus according to the present embodiment is the same as that of the fifth embodiment except that an electric heater 226 is formed between the major surface 203A of the dielectric member 203 and the FS electrode layer 210. FIG. 17 is a cross-sectional view schematically showing a structure of the plasma processing apparatus. FIG. 18 is a plan view showing an example of the electric heater 226. Respective constituent elements of this embodiment corresponding to those of the fifth embodiment are referred to by the common symbols.

As shown in FIG. 18, the electric heater 226 includes a line-shaped heater electrode 226a formed of high-resistance metal. The heater electrode 226a is connected to power feed terminals 227 which penetrate through the dielectric member 203, and the power feed terminals 227 are connected to an AC power supply 228. By supplying electric power from the AC power supply 228 to the power feed terminals 227, the heater electrode 226a is heated. For example, tungsten (W) is preferably used as the high-resistance metal. The line-shaped heater electrode 226a is drawn in, for example, a serpentine-type shape.

It is preferable that the heater electrode 226a is disposed so as not to protrude from the electrode region 210a of the FS electrode layer 210. Consequently, it is possible to suppress a loss of radio frequency power when the dielectric magnetic field generated by supplying the radio frequency power to the induction coil 215 passes through the non-electrode region 210b.

The above-described structure is merely as an example, and the positional relation of the electric heater 226 and the FS electrode layer 210 may be inverted. Particularly, the electric heater 226 is preferably disposed on a side closer to the dielectric member 203. This is because the dielectric member 203 is efficiently heated.

The electric heater 226 and the FS electrode layer 210 laminated thereon are formed in the following manner.

At first, a predetermined number of through holes are formed in the dielectric member 203. Conductor is filled or inserted in the through holes to form the power feed terminals 212, 227.

Next, the heater electrode 226a is formed on the major surface 203A of the dielectric member 203. The heater electrode 226a can be formed by thermal spraying high-resistance metal such as tungsten on the major surface 203A via a mask corresponding to the heater electrode 226a. Alternatively, the heater electrode 226a may be formed by bending a tungsten wire into a shape of the heater electrode 226a, and thereafter fixing the tungsten wire on the major surface 203A. In this case, the heater electrode 226a formed by the thermal-sprayed pattern or by means of other methods is electrically connected to the power feed terminals 227. A thickness of the heater electrode 226a is, for example, in a range from 10 to 300 μm.

Next, the insulation film is formed so as to entirely cover the heater electrode 226a. As a method for forming the insulation film, a method similar to the exemplified method described in the fifth embodiment for forming the insulating film covering the electrode region 210a may be used. In order to enhance adhesiveness between the dielectric member 203 and the insulation film, before forming the insulation film, an adhesion layer may be formed by thermal spraying yttrium or the like on the major surface 203A. A thickness of the electric heater 226 is, for example, in a range from 10 to 300 μm. Subsequently, the FS electrode layer 210 is formed on the electric heater 226. The FS electrode layer 210 can be formed in a similar way as to the above-described method.

Electric power is supplied to the electric heater 226 from the AC power supply 228, and temperature of the dielectric member 203 is controlled. By heating the dielectric member 203, non-volatile material adhering to the cover 208 is easily removed. By controlling the temperature of the dielectric member 203, even when the plasma processing is repeated or continues for a long time, the temperature of the dielectric member 203 can be maintained within a predetermined range, and time-dependent change of etching characteristics can be reduced.

### Eleventh Embodiment

In a plasma processing apparatus according to the present embodiment, a recess portion 203a is formed in the surface of the dielectric member 203 on the coil side, and at least a part of the induction coil 215 is disposed in the recess portion 203a. FIG. 19 is a cross-sectional view schematically showing a structure of the plasma processing apparatus. Respective constituent elements of this embodiment corresponding to those of the fifth embodiment are referred to by the common symbols.

The dielectric member 203 is partially thin by the recess portion 203a. At least a part of the induction coil 215 is disposed in the recess portion 203a, whereby the part of the induction coil 215 disposed in the recess portion 203a is made closer to the reaction chamber 201. Consequently, a loss of radiofrequency power can be suppressed. Since the recess portion 203a can be partially formed on one surface of the plate-shaped dielectric member 203, deterioration of a mechanical strength of the dielectric member 203 is suppressed.

A depth of the recess portion 203a is not limited to a particular size. Even if the recess portion 203a is shallow, effect of suppressing a loss of the radio frequency power can be obtained to some extent. In this respect, the recess portion 203a is preferably formed to have the maximum depth D203a in a range from 0.25T203 to 0.45T203, where T203 is a thickness of the plate-shaped dielectric member 203 having a uniform thickness before forming the recess portion 203a. From a viewpoint of ensuring strength, a ratio (100 s/S (%)) of an area s of the recess portion 203a formed in the surface of the dielectric member 203a with respect to the entire area S of the surface of the dielectric member 203a is preferably set to be in a range from 2 to 50%.

The recess portion 203a may be formed by machining the dielectric member 203 in such a manner of cutting one of the surfaces of the plate-shaped dielectric member 203 having a uniform thickness and having both flat surfaces. As shown in FIG. 11, in a case in which the induction coil 215 is formed to have a spiral shape, if the recess portion 203a is formed to have a spiral shape, substantially entire part of the induction coil 215 can be disposed in the recess portion 203a. Alternatively, the recess portion 203a may have an annular shape having a center substantially the same as the center of the induction coil 215. In this case, FIG. 19, a part of the conductor 215a located in an outer peripheral portion of the induction coil 215 is disposed in the recess portion 203a.

The plasma processing apparatus according to one or more embodiments of the present invention is useful for a process requiring high maintainability and high density plasma, and is applicable to various plasma processing apparatuses such as a dry etching apparatus, a plasma CVD apparatus, etc.

What is claimed is:

1. A plasma processing apparatus comprising:
a vessel which comprises a reaction chamber, atmosphere within the reaction chamber capable of being depressurized;
a lower electrode which supports an object to be processed within the reaction chamber;
a dielectric member which comprises a first surface and a second surface opposite to the first surface, and which closes an opening of the vessel such that the first surface opposes an outside of the reaction chamber and the second surface opposes the object to be processed; and
a coil which opposes the first surface of the dielectric member, and which generates plasma within the reaction chamber,
wherein an electrode pattern and an insulation film which covers the electrode pattern are formed on the second surface of the dielectric member.

2. The plasma processing apparatus according to claim 1,
wherein the electrode pattern comprises an electric heater which heats the dielectric member.

3. The plasma processing apparatus according to claim 1,
wherein the electrode pattern comprises a plate electrode which is capacitively coupled to the plasma within the reaction chamber when radio frequency power is supplied to the dielectric member.

4. The plasma processing apparatus according to claim 1,
wherein the electrode pattern comprises a thermal-sprayed pattern.

5. The plasma processing apparatus according to claim 1,
wherein a first electrode pattern and a first insulation film which covers the first electrode pattern are formed on the second surface of the dielectric member,
wherein a second electrode pattern and a second insulation film which covers the second electrode pattern are formed on a surface of the first insulation film, and
wherein one of the first electrode pattern and the second electrode pattern comprises an electric heater which heats the dielectric member, and the other of the first electrode pattern and the second electrode pattern comprises a plate electrode which is capacitively coupled to the plasma in the reaction chamber when radio frequency power is supplied to the dielectric member.

6. The plasma processing apparatus according to claim 5,
wherein the first electrode pattern comprises the electric heater, and the second electrode pattern comprises the plate electrode.

7. The plasma processing apparatus according to claim 5,
wherein at least one of the first electrode pattern and the second electrode pattern comprises a thermal-sprayed pattern.

8. The plasma processing apparatus according to claim 5,
wherein the electric heater as a whole is disposed within the plate electrode as viewed from a direction perpendicular to the second surface of the dielectric member.

9. The plasma processing apparatus according to claim 1,
wherein the second surface of the dielectric member comprises a flat portion, and
wherein the electrode pattern is formed in the flat portion.

10. The plasma processing apparatus according to claim 1,
wherein a groove is formed on the first surface of the dielectric member, and
wherein at least a part of the coil is disposed in the groove.

11. The plasma processing apparatus according to claim 10,
wherein the groove has an annular shape having a center which substantially overlaps with a center of the coil as viewed from a direction perpendicular to the first surface of the dielectric member.

12. The plasma processing apparatus according to claim 11,
wherein a depth of the groove increases continuously or stepwise toward outside from the center of the annular shape.

13. The plasma processing apparatus according to claim 10,
wherein the coil comprises a conductor having a length L and extending from a first end on a center side to a second end on an outer peripheral side,
wherein the conductor comprises a center side portion having a length 0.5 L from a center of the coil and a remaining outer peripheral side portion, and
wherein a ratio of the remaining outer peripheral side portion disposed within the groove is larger than a ratio of the center side portion disposed within the groove.

14. The plasma processing apparatus according to claim 13,
wherein a winding density of the coil in the outer peripheral side portion is larger than a winding density of the coil in the center side portion.

15. A plasma processing apparatus comprising:
a reaction chamber;
a stage which supports an object to be processed within the reaction chamber;
a cover which opposes the stage within the reaction chamber;
a Faraday shield electrode which is disposed on an opposite side of the stage across the cover;
a dielectric member which is disposed on the opposite side of the stage across the cover, and which closes an opening of the reaction chamber; and
an induction coil which is disposed on an outer side of the dielectric member opposite to the reaction chamber,
wherein the Faraday shield electrode has at least one of a slit portion and a window portion,
wherein a gas introduction path into which material gas of plasma is introduced is formed between the cover and the dielectric member, and
wherein the cover has a gas injection port which is formed in a portion opposing at least a part of the slit portion and the window portion, and through which the material gas introduced into the gas introduction path is supplied into the reaction chamber.

16. The plasma processing apparatus according to claim 15,
wherein the cover has a plurality of gas injection ports formed in the portion opposing at least a part of the slit portion and the window portion.

17. The plasma processing apparatus according to claim 15,
wherein the cover has a groove formed in the portion opposing at least a part of the slit portion and the window portion, and
wherein the gas injection port is formed on an inner side of the groove.

18. The plasma processing apparatus according to claim 15,
wherein the Faraday shield electrode is disposed between the dielectric member and the cover.

19. The plasma processing apparatus according to claim 18,
wherein a recess portion is formed on a surface of the dielectric member opposing the induction coil, and
wherein at least a part of the induction coil is disposed in the recess portion.

20. The plasma processing apparatus according to claim 15,
wherein the Faraday shield electrode is disposed between the dielectric member and the induction coil.
